(19) United States
(12) Patent Application Publication
(10) Pub. No.: US 2025/0297968 A1
(43) Pub. Date: Sep. 25, 2025

(54) INSPECTION DEVICE AND INSPECTION METHOD

(71) Applicant: Tokyo Seimitsu Co., Ltd., Tokyo (JP)

(72) Inventors: Yoshiyuki KAWATA, Tsuchiura-city (JP); Katsufumi MORIYAMA, Tsuchiura-city (JP); Hideki MORII, Tsuchiura-city (JP); Kazuyuki SANADA, Tsuchiura-city (JP); Akira YAMAGUCHI, Tokyo (JP); Tetsuo YOSHIDA, Tokyo (JP); Hiroshi NISHIMURA, Tokyo (JP)

(73) Assignee: Tokyo Seimitsu Co., Ltd., Tokyo (JP)

(21) Appl. No.: 19/233,613

(22) Filed: Jun. 10, 2025

Related U.S. Application Data
(63) Continuation of application No. PCT/JP2023/043246, filed on Dec. 4, 2023.

(30) Foreign Application Priority Data
Dec. 13, 2022 (JP) 2022-198600
Dec. 13, 2022 (JP) 2022-198601
Dec. 13, 2022 (JP) 2022-198602

(51) Int. Cl. G01N 21/95; G01B 11/24; G01N 21/88

(52) U.S. Cl. CPC G01N 21/9501; G01B 11/2441; G01N 21/8851; G01N 2021/8874; G01N 2021/888

(57) ABSTRACT

An inspection device includes: a camera configured to capture an image of an inspection object on a wafer; a first determining unit configured to detect the inspection object from the image captured by the camera and make a tentative determination of quality of the inspection object; a three-dimensional shape measuring machine configured to measure a three-dimensional shape of the inspection object determined to be abnormal by the tentative determination; and a second determining unit configured to make a formal determination of the quality of the inspection object based on the three-dimensional shape of the inspection object measured by the three-dimensional shape measuring machine and the image captured by the camera or based on the three-dimensional shape of the inspection object measured by the three-dimensional shape measuring machine.

### CROSS-REFERENCE TO RELATED APPLICATIONS

The present application is a Continuation of PCT International Application No. PCT/JP2023/043246 filed on Dec. 4, 2023 claiming priority under 35 U.S.C § 119(a) to Japanese Patent Application Nos. 2022-198600, 2022-198601 and 2022-198602 filed on Dec. 13, 2022. Each of the above applications is hereby expressly incorporated by reference, in their entirety, into the present application.

### BACKGROUND OF THE INVENTION

### Field of the Invention

The present disclosure relates to an inspection device and an inspection method and, particularly, to a technique for inspecting a semiconductor device formed on a semiconductor wafer.

### Description of the Related Art

In a manufacturing process of a semiconductor device, various inspections are performed in various manufacturing steps in order to guarantee product quality and improve yield. For example, a plurality of chips corresponding to each semiconductor device are formed on a semiconductor wafer (hereinafter, referred to as a “wafer”), and then an electrode pad of the semiconductor device is brought into contact with a probe needle of a probe card and a test signal is supplied in a wafer-level inspection. A signal output by the semiconductor device in response to the test signal is then measured by a tester to electrically inspect whether the semiconductor device operates normally.

In a wafer-level inspection as described above, ideally, only an oxide film on a surface of the electrode pad is scraped off with a probe needle and the probe needle is brought into contact with the electrode pad to make the electrode pad conductive. In the wafer-level inspection, overdrive is applied to scrape off the oxide film on the surface of the electrode pad with a probe needle. In addition, in a visual inspection of a wafer, detection of needle marks formed on the electrode pad is performed after the wafer-level inspection.

If no needle marks are detected from the electrode pad in the detection of needle marks after the wafer-level inspection, the measurement is determined to be a failure. On the other hand, if the probe needle pierces the electrode pad and exposes an underlying layer of the electrode pad, the electrode pad is treated as defective.

PTL 1 discloses a needle mark inspection device for automatically detecting an exposure status of an underlying layer of an electrode pad after inspection with a probe needle. In PTL 1, a camera is used to capture an image of needle marks formed on the electrode pad to inspect whether or not the underlying layer of the electrode pad is exposed.

### Citation List

PTL 1: Japanese Patent Application Laid-Open No. 2009-289818.

PTL 2: Japanese Patent Application Laid-Open No. 2022-133631.

### SUMMARY OF THE INVENTION

In a visual inspection of a wafer, for example, an image (two-dimensional image) of the wafer captured by a camera may be inspected for the presence or absence of scratches (for example, scratches on a plain wafer with no pattern formed or on a mirror wafer) or foreign objects in addition to the inspection of the needle marks described above.

In a visual inspection of a wafer, for example, in the detection of needle marks after a wafer-level inspection, the wafer is illuminated by illumination means after the wafer-level inspection and an image (two-dimensional image) of an upper surface of the wafer is captured by a camera as described in PTL 1. In addition, the electrode pad and the underlying layer are distinguished from one another based on brightness/darkness of the image.

When distinguishing between the electrode pad and the underlying layer based on the brightness/darkness of the image as described above, it may be difficult to determine whether the brightness/darkness of the image is attributable to how light strikes the wafer surface due to the shape of the wafer surface or attributable to differences in materials. For example, when the proportion of dark areas attributable to the shape of the wafer surface is large, the electrode pad may be determined to be defective even if the underlying layer is not exposed.

In addition, in a visual inspection of a wafer for scratches or foreign objects using a two-dimensional image, depending on the material of the wafer or the shape or type of scratches or foreign objects, there may be cases where sufficient accuracy cannot be obtained in order to make a quality determination of a result of the visual inspection.

For this reason, a three-dimensional shape of needle marks may conceivably be measured using a three-dimensional shape measuring machine capable of contactless measurement of a three-dimensional shape of an inspection object. For example, PTL 2 discloses a particle measuring apparatus that uses a three-dimensional shape measuring machine to calculate an amount of particles generated when a probe needle comes into contact with an electrode pad based on a volume difference between a volume of concave parts that are depressed from a reference surface of the electrode pad and a volume of convex parts that protrude from the reference surface.

However, the measurement of the three-dimensional shape of an electrode pad by a three-dimensional shape measuring machine is time-consuming. For example, it takes several days or more to complete inspection of a lot to be inspected, thereby causing a decline in manufacturing efficiency of semiconductor devices (chips).

In addition, when a wafer after a wafer-level inspection is placed on a stage for visual inspection as described above, air disturbances may occur due to temperature irregularities. Such air disturbances can cause a decline in the accuracy of measurements made by the three-dimensional shape measuring machine. For example, when a white interference microscope is used as the three-dimensional shape measuring machine, an interference lens is easily affected by temperature. There is a trade-off between a decline in inspection accuracy attributable to a disturbance such as the air disturbance described above and an increase in inspection time due to waiting until the disturbance subsides.

The present disclosure has been made in consideration of such circumstances and an object thereof is to provide an inspection device and an inspection method capable of performing accurate and fast visual inspections of wafers.

An inspection device according to a first aspect of the present disclosure includes: a camera configured to capture an image of an inspection object on a wafer; a first determining unit configured to detect the inspection object from the image captured by the camera and make a tentative determination of quality of the inspection object; a three-dimensional shape measuring machine configured to measure a three-dimensional shape of the inspection object determined to be abnormal by the tentative determination; and a second determining unit configured to make a formal determination of the quality of the inspection object based on the three-dimensional shape of the inspection object measured by the three-dimensional shape measuring machine and the image captured by the camera or based on the three-dimensional shape of the inspection object measured by the three-dimensional shape measuring machine.

According to the first aspect, a tentative determination of the quality of an electrode pad using a camera capable of making the tentative determination at high speed can be made prior to a formal determination of the quality by a three-dimensional shape measuring machine to narrow down objects of the formal determination. As a result, the three-dimensional shape measuring machine can accurately inspect needle marks formed on the surface of the electrode pad by a wafer-level inspection and reduce the time required for quality determination.

An inspection device according to a second aspect of the present disclosure is the inspection device according to the first aspect, wherein the inspection object includes a needle mark formed on an electrode pad of the wafer when electrically inspecting the wafer using a test head.

An inspection device according to a third aspect of the present disclosure is the inspection device according to the second aspect, wherein the first determining unit detects an area of a needle mark formed on the electrode pad from the image captured by the camera and makes a tentative determination of quality of the electrode pad based on the area.

An inspection device according to a fourth aspect of the present disclosure is the inspection device according to the second or third aspect, wherein the second determining unit makes a formal determination of quality of the electrode pad based on a maximum pit depth of the electrode pad measured by the three-dimensional shape measuring machine.

An inspection device according to a fifth aspect of the present disclosure is the inspection device according to any of the first to fourth aspects, further including an alignment unit configured to acquire a positional relationship between the camera and the three-dimensional shape measuring machine.

An inspection device according to a sixth aspect of the present disclosure is the inspection device according to the fifth aspect, wherein the alignment unit acquires a positional relationship between the camera and the three-dimensional shape measuring machine based on measurement results of an alignment mark by the camera and the three-dimensional shape measuring machine.

An inspection method according to a seventh aspect of the present disclosure includes: capturing an image of an inspection object on a wafer with a camera, detecting the inspection object from the image, and making a tentative determination of quality of the inspection object; and measuring a three-dimensional shape of the inspection object determined to be abnormal by the tentative determination with a three-dimensional shape measuring machine and making a formal determination of the quality of the inspection object based on the three-dimensional shape of the inspection object measured by the three-dimensional shape measuring machine and the image captured by the camera or based on the three-dimensional shape of the inspection object measured by the three-dimensional shape measuring machine.

An inspection method according to an eighth aspect of the present disclosure is the inspection method according to the seventh aspect, wherein the inspection object includes a needle mark formed on an electrode pad of the wafer when electrically inspecting the wafer using a test head.

An inspection method according to a ninth aspect of the present disclosure is the inspection method according to the seventh or eighth aspect, further including an alignment step of acquiring a positional relationship between the camera and the three-dimensional shape measuring machine.

An inspection method according to a tenth aspect of the present disclosure is the inspection method according to the ninth aspect, further including: measuring an alignment mark with the camera; and measuring the alignment mark with the three-dimensional shape measuring machine, wherein in the alignment step, a positional relationship between the camera and the three-dimensional shape measuring machine is acquired based on measurement results of the alignment mark by the camera and the three-dimensional shape measuring machine.

The inspection device according to an eleventh aspect of the present disclosure includes: a three-dimensional shape measuring machine configured to measure a three-dimensional shape of an inspection object on a wafer; and a calculating unit configured to calculate a measurement cost for measuring the inspection object on the wafer based on inspection object arrangement information related to an arrangement of the inspection object and a size of a measurement field of view of the three-dimensional shape measuring machine.

According to the eleventh aspect, appropriately setting the size of the measurement field of view of the three-dimensional shape measuring machine enables a needle mark formed by a wafer-level inspection to be inspected accurately and at high speed.

An inspection device according to a twelfth aspect of the present disclosure is the inspection device according to the eleventh aspect, further including: a selecting unit configured to output the measurement cost calculated by the calculating unit and select a size of a measurement field of view when inspecting the inspection object in response to an operation input from an operator.

An inspection device according to a thirteenth aspect of the present disclosure is the inspection device according to the eleventh aspect, wherein the calculating unit calculates the measurement cost for each size of the measurement field of view based on the inspection object arrangement information and selects a size of the measurement field with the measurement cost that satisfies a set criterion.

An inspection device according to a fourteenth aspect of the present disclosure is the inspection device according to any of the eleventh to thirteenth aspects, wherein the measurement cost includes information related to a scanning speed when the wafer and the three-dimensional shape measuring machine are scanned in a height direction, and the calculating unit calculates the scanning speed such that the narrower the measurement field of view of the three-dimensional shape measuring machine, the larger a calculated value of the scanning speed.

An inspection device according to a fifteenth aspect of the present disclosure is the inspection device according to any of the eleventh to fourteenth aspects, wherein the measurement cost includes information related to a measurement time required to measure an inspection object on the wafer, and the calculating unit calculates the measurement time such that the narrower the measurement field of view of the three-dimensional shape measuring machine or the larger the number of inspection objects to be included in the measurement field of view, the smaller a calculated value of the measurement time.

An inspection device according to a sixteenth aspect of the present disclosure is the inspection device according to any of the eleventh to fifteenth aspects, further including a measurement field of view moving unit configured to move the measurement field of view so that when inspecting the inspection object formed on the wafer, an inspection object that has already been inspected is not included in the measurement field of view.

An inspection device according to a seventeenth aspect of the present disclosure is the inspection device according to any of the eleventh to sixteenth aspects, wherein the inspection object includes a needle mark formed on an electrode pad of the wafer when electrically inspecting the wafer using a test head.

An inspection method according to an eighteenth aspect of the present disclosure includes: calculating a measurement cost for measuring an inspection object on a wafer based on inspection object arrangement information related to an arrangement of the inspection object on the wafer and a size of a measurement field of view of a three-dimensional shape measuring machine; and setting the calculated size of the measurement field of view to the three-dimensional shape measuring machine.

An inspection device according to a nineteenth aspect of the present disclosure includes: a measurement unit including a measuring chamber surrounded by a partition wall configured to separate inside and outside air environments; and a three-dimensional shape measuring machine configured to be attached to and detached from a first opening provided on the partition wall of the measurement unit and that measures a three-dimensional shape of an inspection object on a wafer in the measuring chamber in a contactless manner.

According to the nineteenth aspect, surrounding the measuring chamber with a partition wall for separating inside and outside air environments enables an effect of a disturbance to the inside of the measuring chamber to be minimized and prevents a decline in inspection accuracy of the three-dimensional shape of the inspection object attributable to air disturbance.

An inspection device according to a twentieth aspect of the present disclosure is the inspection device according to the nineteenth aspect, wherein the partition wall of the measuring chamber has at least one of a light-blocking property and an anti-vibration property.

An inspection device according to a twenty-first aspect of the present disclosure is the inspection device according to the nineteenth or twentieth aspect, including a first shutter provided on a second opening provided on the partition wall of the measurement unit, wherein the wafer is carried into and out from the measuring chamber via the second opening.

An inspection device according to a twenty-second aspect of the present disclosure is the inspection device according to any of the nineteenth to twenty-first aspects, further including a cover configured to cover the three-dimensional shape measuring machine when the three-dimensional shape measuring machine is attached to the measurement unit for separating inside and outside air environments.

An inspection device according to a twenty-third aspect of the present disclosure is the inspection device according to the twenty-second aspect, wherein the cover has at least one of a light-blocking property and an anti-vibration property.

An inspection device according to a twenty-fourth aspect of the present disclosure is the inspection device according to any of the nineteenth to twenty-first aspects, including a transparent member configured to be attached to the first opening, wherein the three-dimensional shape measuring machine measures the inspection object in the measuring chamber via the transparent member.

An inspection device according to a twenty-fifth aspect of the present disclosure is the inspection device according to any of the nineteenth to twenty-fourth aspects, including: a fan attached to a third opening provided on the partition wall of the measurement unit to cause air inside the measuring chamber to circulate; and a fan shutter configured to open and close the third opening.

An inspection device according to a twenty-sixth aspect of the present disclosure is the inspection device according to any of the nineteenth to twenty-fifth aspects, including: a loader unit including a preparation chamber surrounded by a partition wall configured to separate inside and outside air environments; and a second shutter provided on an opening provided on the partition wall of the loader unit, wherein the wafer is carried into and out from the preparation chamber via the opening of the loader unit.

An inspection device according to a twenty-seventh aspect of the present disclosure is the inspection device according to the twenty-sixth aspect, wherein the partition wall of the preparation chamber has at least one of a light-blocking property and an anti-vibration property.

An inspection device according to a twenty-eighth aspect of the present disclosure is the inspection device according to any of the nineteenth to twenty-seventh aspects, including a test head configured to be attached to and detached from the first opening of the measurement unit, wherein the inspection object includes a needle mark formed on an electrode pad when electrically inspecting a wafer using a test head.

An inspection device according to a twenty-ninth aspect of the present disclosure is the inspection device according to the twenty-eighth aspect, including: a first attaching unit formed on the partition wall of the measurement unit; a second attaching unit formed on the test head in a shape to be attached to the first attaching unit; and a third attaching unit formed on the three-dimensional shape measuring machine in a shape to be attached to the first attaching unit.

An inspection device according to a thirtieth aspect of the present disclosure is the inspection device according to the twenty-ninth aspect, wherein the second attaching unit and the third attaching unit are formed in a shape to be fitted to the first attaching unit.

According to the present disclosure, using a three-dimensional shape measuring machine enables needle marks formed on a surface of an electrode pad by a wafer-level inspection to be accurately inspected and the time required for inspection to be reduced.

### BRIEF DESCRIPTION OF THE DRAWINGS

FIG. 1 is a diagram (during wafer-level inspection) illustrating an inspection device according to a first embodiment of the present disclosure;

FIG. 2 is a diagram (during inspection of electrode pad) illustrating the inspection device according to the first embodiment of the present disclosure;

FIG. 3 is a block diagram illustrating a control system of the inspection device according to the first embodiment of the present disclosure;

FIG. 4 is a flowchart illustrating an inspection method according to the first embodiment of the present disclosure;

FIG. 5 is a diagram illustrating an example of a captured image of an electrode pad captured by a 2D camera;

FIG. 6 is a diagram illustrating an example of measured data obtained by measuring an electrode pad that is an object of a formal determination with a 3D shape measuring machine;

FIG. 7 is a diagram for explaining a feature amount (maximum pit depth) of a needle mark formed on an electrode pad;

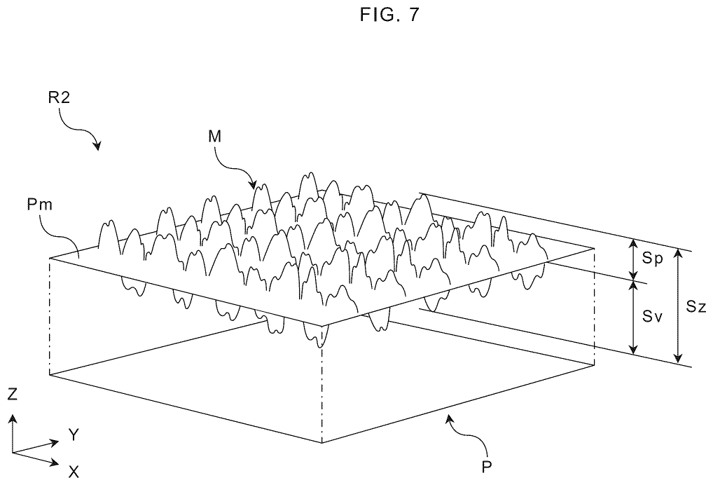

FIG. 8 is a flowchart illustrating an inspection method according to a modification of the first embodiment;

FIG. 9 is a flowchart (continued) illustrating the inspection method according to the modification of the first embodiment;

FIG. 10 is a diagram (during wafer-level inspection) illustrating an inspection device according to a second embodiment of the present disclosure;

FIGS. 11A to 11C each include a plan view and a front view illustrating examples of an alignment mark;

FIG. 12 is a flowchart illustrating procedures of alignment of a 2D camera and a 3D shape measuring machine;

FIG. 13 is a diagram illustrating an example of a captured image of an alignment mark;

FIG. 14 is a plan view for explaining a positional relationship between a 2D camera and a 3D shape measuring machine;

FIG. 15 is a plan view for explaining a positional relationship between a 2D camera and a 3D shape measuring machine;

FIG. 16 is a diagram (during wafer-level inspection) illustrating an inspection device according to a third embodiment of the present disclosure;

FIG. 17 is a flowchart illustrating procedures of alignment of a 2D camera and a 3D shape measuring machine;

FIG. 18 is a block diagram illustrating an example of a 2D camera;

FIG. 19 is a diagram illustrating examples of a field of view of a 2D camera and a spot of a beam;

FIG. 20 is a diagram (during wafer-level inspection) illustrating an inspection device according to a fourth embodiment of the present disclosure;

FIG. 21 is a diagram (during inspection of electrode pad) illustrating the inspection device according to the fourth embodiment of the present disclosure;

FIG. 22 is a block diagram illustrating a control system of the inspection device according to the fourth embodiment of the present disclosure;

FIG. 23 is a plan view of a wafer;

FIG. 24 is an enlarged plan view of a chip (region XXIV in FIG. 23);

FIG. 25 is a table illustrating an example of a measurement time of an electrode pad;

FIG. 26 is a block diagram illustrating a function of setting a scanning speed in a Z direction of a 3D shape measuring machine and a wafer;

FIG. 27 is a block diagram illustrating a function of setting a size of a measurement field of view of a 3D shape measuring machine;

FIG. 28 is a diagram for explaining measurement procedures of an electrode pad;

FIG. 29 is a diagram for explaining a feature amount (maximum pit depth) of a needle mark M formed on an electrode pad;

FIG. 30 is a diagram (during wafer-level inspection) illustrating an inspection device according to a fifth embodiment of the present disclosure;

FIG. 31 is a diagram (during inspection of electrode pad) illustrating the inspection device according to the fifth embodiment of the present disclosure;

FIG. 32 is a block diagram illustrating a control system of the inspection device according to the fifth embodiment of the present disclosure;

FIG. 33 is a diagram (during wafer-level inspection) illustrating an inspection device according to a first modification of the fifth embodiment;

FIG. 34 is a diagram (during wafer-level inspection) illustrating an inspection device according to a second modification of the fifth embodiment;

FIG. 35 is a diagram illustrating a test head and a 3D shape measuring machine in an inspection device according to a third modification of the fifth embodiment; and

FIG. 36 is a flowchart illustrating an inspection method according to the fifth embodiment of the present disclosure.

### DESCRIPTION OF THE EMBODIMENTS

Hereinafter, embodiments of an inspection device and an inspection method will be described with reference to the accompanying drawings.

### First Embodiment

In the present embodiment, while a case where detection of needle marks formed on an electrode pad P of a wafer W is performed after a wafer-level inspection will be described as an example of a visual inspection of a wafer, the present disclosure is not limited thereto. For example, the present embodiment is also applicable to a measurement (detection) of any inspection object (for example, a scratch or a foreign object) on the wafer W.

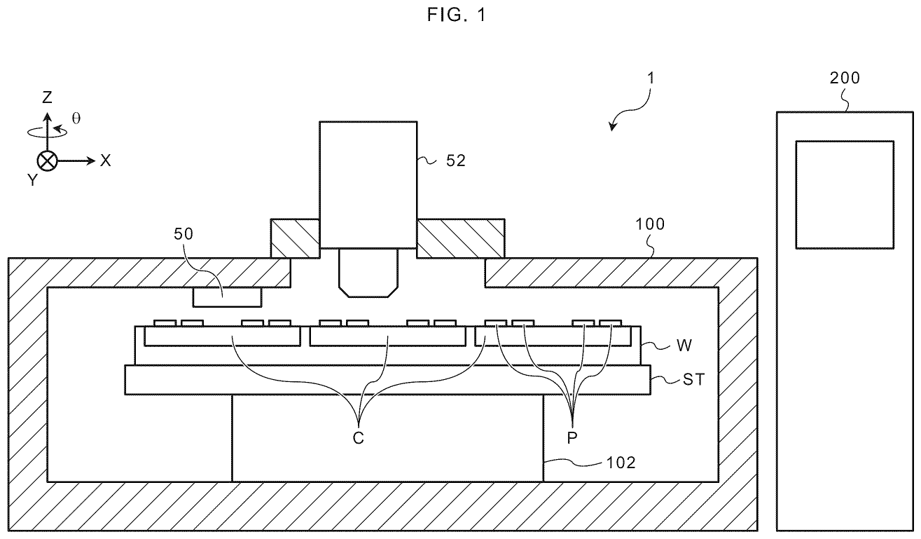

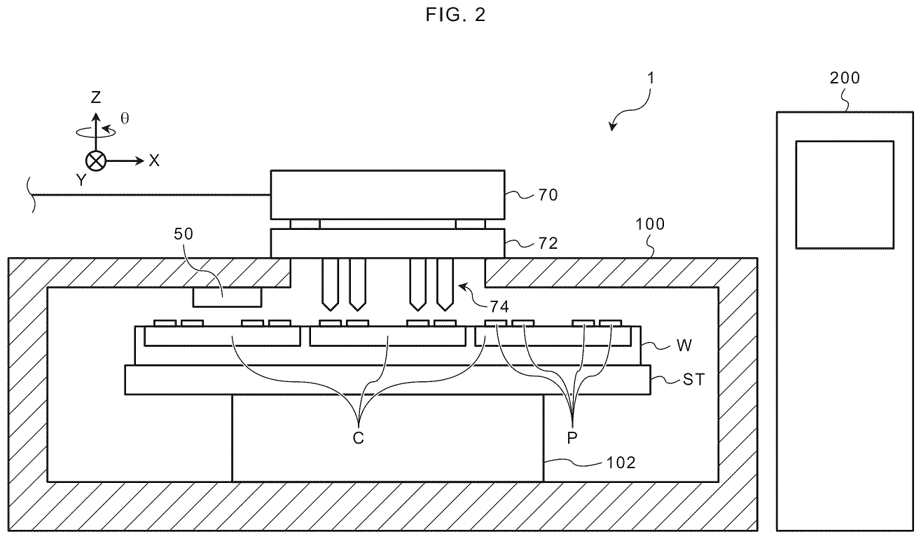

FIGS. 1 and 2 are diagrams illustrating an inspection device according to the first embodiment of the present disclosure. FIG. 2 illustrates a state upon execution of a wafer-level inspection, and FIG. 1 illustrates a state upon inspection (detection of needle marks) of the electrode pad P of the wafer W after the wafer-level inspection.

Upon execution of the wafer-level inspection, as illustrated in FIG. 2, a test head 70 is attached to a housing of a measurement unit 100 of an inspection device 1. Next, a probe needle 74 of a probe card 72 is brought into contact with the electrode pad P formed on a surface of the wafer W that is an inspection object and a test signal is supplied. A signal output by the semiconductor device (chip C) in response to the test signal is then measured by a tester to electrically inspect whether the semiconductor device operates normally. In the wafer-level inspection, a part of an oxide film on a surface of the electrode pad P is scraped off by the probe needle 74, and the probe needle 74 and the electrode pad P become conductive.

Upon inspection of the electrode pad P of the wafer W, as illustrated in FIG. 1, a three-dimensional shape measuring machine (hereinafter, referred to as a “3D shape measuring machine”) 52 is attached to the measurement unit 100 of the inspection device 1.

In the inspection of the electrode pad P of the wafer W, first, a tentative determination is made using a 2D camera (for example, an imaging unit for alignment of the wafer W) 50. In the tentative determination, an image of the electrode pad P is captured by the 2D camera 50. In addition, a detection of a needle mark formed on the electrode pad P by the wafer-level inspection is performed from the image captured by the 2D camera 50, and a determination of quality (pass/fail) of the detected needle mark is performed. In the determination of the quality of the needle mark using the image captured by the 2D camera 50, the quality of the needle mark is determined based on a feature amount (first feature amount (for example, an area)) related to the needle mark. Specifically, when the area of the needle mark in the electrode pad P exceeds a tentative determination threshold (first threshold), conceivably, it is likely that the needle mark has been deeply excavated and an underlying layer is likely to be exposed. Therefore, when the area of the needle mark in the electrode pad P exceeds the tentative determination threshold (first threshold), the electrode pad P is tentatively determined to be abnormal (fail).

Next, with respect to the electrode pad P determined as “fail” in the tentative determination, a determination (formal determination) of quality (pass/fail) of the needle mark is performed using the 3D shape measuring machine 52.

The 3D shape measuring machine 52 is a device for measuring a three-dimensional shape of the electrode pad P without coming into contact with the surface of the electrode pad P. A measurement method employed by the 3D shape measuring machine 52 is not particularly limited and examples of measurement methods that can be applied include white light interferometry, SD-OCT (Spectral Domain Optical Coherence Tomography), FD-OCT (Fourier Domain Optical Coherence Tomography), a laser confocal method, a triangulation method, an optical cutting method, a pattern projection method, an optical comb method, and a focus variation method. In addition, as the 3D shape measuring machine 52 using white light interferometry, for example, the 3D shape measuring machine described in Japanese Patent Application Laid-Open No. 2016-080564 or Japanese Patent Application Laid-Open No. 2016-161312 can be applied.

In the determination of quality of the needle mark using the 3D shape measuring machine 52, only the electrode pad P determined as “fail” in the tentative determination is considered an object of the formal determination. Then, with respect to the electrode pad P that is an object of the formal determination, a shape of the electrode pad P is measured using the 3D shape measuring machine 52 and a feature amount (second feature amount (for example, a maximum pit depth Sv of the needle mark formed in the electrode pad P)) of the electrode pad P is obtained. In this case, the maximum pit depth Sv is a parameter defined by JIS (Japanese Industrial Standards) B 0681-2: 2018 or ISO (International Organization for Standardization) 25178-2: 2012. When the maximum pit depth Sv exceeds a formal determination threshold (second threshold), since it is likely that the underlying layer is exposed by the needle mark and circuitry is damaged, a determination of “abnormal” (fail) is made.

According to the present embodiment, using the 3D shape measuring machine 52 enables a needle mark formed by a wafer-level inspection to be inspected accurately. In addition, in the present embodiment, since a quality determination using the 2D camera 50 capable of executing the quality determination at high speed is made prior to a quality determination by the 3D shape measuring machine 52 to narrow down objects of the formal determination, the time required for the quality determination can be reduced.

### Configuration of Inspection Device

As illustrated in FIGS. 1 and 2, the inspection device 1 according to the present embodiment includes the measurement unit 100 and a loader unit 200 that supplies and retrieves the wafer W that is an inspection object to and from the measurement unit 100. The measurement unit 100 and the loader unit 200 are separable. Note that although the measurement unit 100 and the loader unit 200 can be provided in plurality, only one each is illustrated for the sake of simplicity of description.

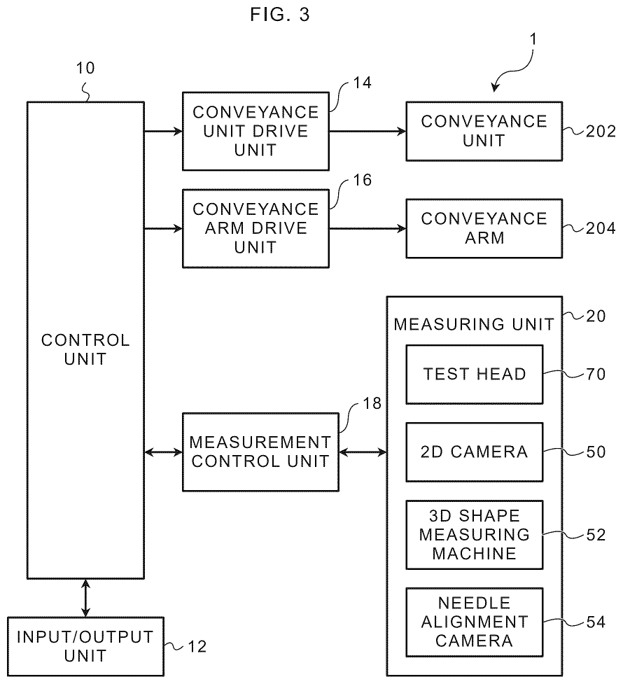

The loader unit 200 includes a load port on which a wafer cassette is placed and a conveyance unit 202 (refer to FIG. 3) which conveys the wafer W between each measurement unit 100 of the measurement units 100 and the wafer cassette.

When the wafer W is supplied from the loader unit 200 to each measurement unit 100, the wafer W is held by suction on a holding surface of a stage ST of each measurement unit 100.

A stage movement mechanism 102 supports a lower surface (a surface on an opposite side to the holding surface on which the wafer W is held by suction) of the stage ST. The stage movement mechanism 102 is configured to move in XYZ directions and rotatable in a θ direction (a rotation direction around the Z direction). Accordingly, due to the stage movement mechanism 102, the wafer W held by suction on the holding surface of the stage ST is movable in the XYZ directions and rotatable in the θ direction together with the stage ST.

As illustrated in FIG. 2, upon execution of the wafer-level inspection, the test head 70 is attached to the measurement unit 100 of the inspection device 1.

The probe card 72 is provided at a position opposing the stage ST and arranged approximately parallel to the holding surface of the stage ST. Probe needles 74 are formed on the surface opposing the stage ST of the probe card 72. The probe card 72 is connected to a tester body via the test head 70.

Chips C are formed on the wafer W, and each chip C includes one or more electrode pads P. By moving the stage ST in the XYZ directions or rotating the stage ST in the θ direction with the stage movement mechanism 102, positioning of the wafer W and the probe card 72 is performed so as to bring each probe needle 74 into contact with a corresponding electrode pad P.

After positioning and contact of the probe needle 74 and the electrode pad P by the inspection device 1, an electric signal is sent to the chip C from the tester body via the test head 70, the probe card 72, and the probe needle 74 to perform an inspection (wafer-level inspection) of electrical characteristics of the chip C on the wafer W. A result of the inspection of electrical characteristics is output by an input/output unit (refer to FIG. 3) in a form that can be checked by an operator.

After the end of the inspection of electrical characteristics of the chip C on the wafer W, the wafer W is conveyed from the inspection device 1 to the loader unit 200 by a conveyance unit to be retrieved.

As illustrated in FIG. 1, the 3D shape measuring machine 52 is attached to the measurement unit 100 of the inspection device 1 during the inspection of the electrode pad P of the wafer W. In addition, needle marks formed in the electrode pad P by the wafer-level inspection are sequentially detected by the 2D camera 50 and the 3D shape measuring machine 52 to perform quality determination of the needle marks formed on the electrode pad P.

In the present embodiment, a positional relationship between the 2D camera 50 and the 3D shape measuring machine 52 is assumed to be known or calibrated.

In addition, while the 2D camera 50 and the 3D shape measuring machine 52 are separately attached in the present embodiment, the present disclosure is not limited thereto. For example, the 2D camera 50 and the 3D shape measuring machine 52 may be made interchangeable by a revolver mechanism.

Furthermore, while the test head 70 and the 3D shape measuring machine 52 are attachable to and detachable from the measurement unit 100 of the inspection device 1 in the present embodiment, the present disclosure is not limited thereto. For example, a wafer-level inspection and an inspection of the electrode pad P after the wafer-level inspection may be performed by different devices.

In addition, the test head 70, the 2D camera 50, the 3D shape measuring machine 52, and the like and the stage ST need only be relatively movable, and the test head 70, the 2D camera 50, the 3D shape measuring machine 52, and the like may be made movable with respect to the stage ST.

### Control System of Inspection Device

FIG. 3 is a block diagram illustrating a control system of the inspection device according to the first embodiment of the present disclosure.

As illustrated in FIG. 3, the inspection device 1 according to the present embodiment includes a control unit 10, an input/output unit 12, a conveyance unit drive unit 14, a conveyance arm drive unit 16, and a measurement control unit 18.

The control unit 10 includes a processor (for example, a CPU (Central Processing Unit) or an MPU (Micro Processor Unit)), a ROM (Read Only Memory), a RAM (Random Access Memory), and a storage device (for example, an HDD (Hard Disk Drive) or an SSD (Solid State Drive)). In the control unit 10, functions of various units of the inspection device 1 are realized by the processor by executing various programs such as a control program stored in the storage device. The control unit 10 is an example of the first determining unit and the second determining unit.

The input/output unit 12 includes a display unit (for example, a liquid crystal display) that displays a GUI (Graphical User Interface) or the like for operating the inspection device 1 and an operating unit (for example, a touch panel, a keyboard, or a pointing device) for receiving operation input from a user.

The conveyance unit drive unit 14 includes a motor or the like for moving the conveyance unit 202 in the XYZ directions and rotating the conveyance unit 202 in the θ direction (around the Z direction) inside the loader unit 200.

The conveyance arm drive unit 16 includes a motor for extending and contracting a conveyance arm 204 attached to the conveyance unit 202 in a length direction of the conveyance arm 204 and a control valve for suctioning the wafer W to a suction hole of the conveyance arm 204. The control valve is connected to a vacuum (pump) provided at an installation side of the inspection device 1.

The control unit 10 controls the conveyance unit 202 and the conveyance arm 204 by the conveyance unit drive unit 14 and the conveyance arm drive unit 16, respectively, to retrieve the wafer W from wafer cassettes and to carry the wafer W into and out from the measurement units 100.

A needle alignment camera 54 is a device for detecting a tip position of the probe needle 74 and is provided on, for example, the stage ST. The control unit 10 performs positioning of the probe needle 74 and the electrode pad P based on a detection result of the tip position of the probe needle 74 and a detection result of the electrode pad P by the 2D camera 50.

The measurement control unit 18 performs, according to a control signal from the control unit 10, drive control of the test head 70 for inspection of the wafer W provided in the measurement unit 100, imaging control of the 2D camera 50, measurement control of the 3D shape measuring machine 52, and imaging control of the needle alignment camera 54. As the test head 70 and the 2D camera 50, for example, the test head and the 2D camera described in Japanese Patent Application Laid-Open No. 2019-102591 can be used.

### Inspection Method

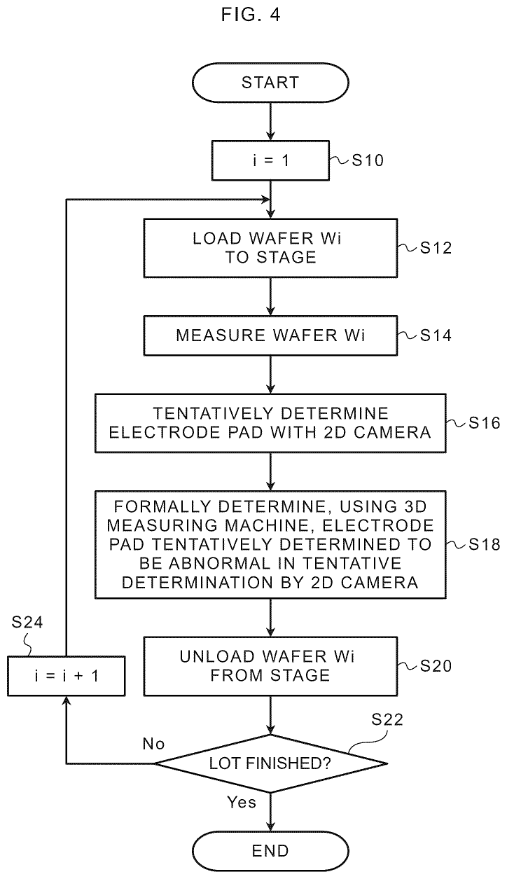

FIG. 4 is a flowchart illustrating an inspection method according to the first embodiment of the present disclosure.

When an inspection of a lot of wafers W is started, a parameter i of the number of wafers W that are inspection objects is set to i=1 (step S10). A first wafer W1 is then loaded to the stage ST (step S12), and a wafer-level inspection of the wafer W1 is executed (step S14).

After the wafer-level inspection, a quality determination of the electrode pad P is performed using the 2D camera 50 and the 3D shape measuring machine 52 (steps S16 and S18).

In step S16, a quality determination of the electrode pad P is performed using the 2D camera 50. The detection of the electrode pad P using the 2D camera 50 can be executed in a short time as compared to when using the 3D shape measuring machine 52. Therefore, in step S16, all of the electrode pads P of the wafer W1 may be considered inspection objects.

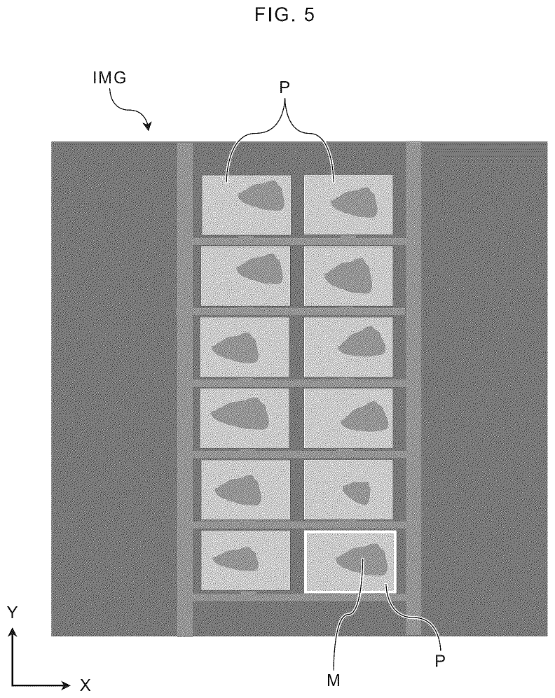

FIG. 5 is a diagram illustrating an example of a captured image IMG of the electrode pad P captured by the 2D camera 50.

In step S16, first, detection of the electrode pad P is performed. As illustrated in FIG. 5, brightness in the captured image IMG differs due to a difference in reflectance to light between a surface of the wafer W (for example, silicon) and a surface of the electrode pad P (for example, aluminum). Specifically, the surface of the electrode pad P is brighter than the surface of the wafer W. The control unit 10 detects the electrode pad P based on the difference between light and dark in the captured image IMG. Note that the control unit 10 may detect the electrode pad P based on a design value of a shape, a size, or an arrangement of the electrode pad P in addition to the difference between light and dark in the captured image IMG.

Next, a needle mark formed in the electrode pad P is detected from the captured image by the 2D camera 50. As illustrated in FIG. 5, since the needle mark M is a portion excavated by the probe needle 74 in the electrode pad P, light is scattered and less likely to reach the side of the 2D camera 50 at the needle mark M. Therefore, the needle mark M becomes darker than portions other than the needle mark M of the electrode pad P. The control unit 10 detects a region darker than its surroundings in the electrode pad P detected from the captured image IMG as the needle mark M.

Note that an order of the detection of the electrode pad P and the detection of the needle mark M is not particularly limited and may be performed sequentially or simultaneously.

Next, the control unit 10 calculates a first feature amount based on a detection result of the needle mark M and performs a tentative determination of quality of the needle mark M. For example, an area of the needle mark M can be used as the first feature amount. When the area of the needle mark M detected from the captured image IMG exceeds a tentative determination threshold (first threshold), since it is likely that the needle mark has been deeply excavated and an underlying layer is likely to be exposed, the control unit 10 tentatively determines the electrode pad P as “abnormal” (fail).

At this point, the quality of the needle mark M may be affected by an amount of movement (dragging distance) of the probe needle 74 on the electrode pad P. Therefore, for example, the tentative determination threshold (first threshold) related to the area of the needle mark M may be set based on a thickness of the probe needle 74 to a value approximately equal to a thickness or a cross-sectional area on an XY plane of the probe needle 74. In this case, conditions for “fail” in the tentative determination can be made stricter, thereby increasing the accuracy of the inspection.

Note that the tentative determination is not limited to the example described above. For example, the tentative determination may be made based on a thickness of the electrode pad P, a ratio of an area of the needle mark M to the electrode pad P, a position, or a strength (brittleness) of the material of the electrode pad P. For example, conceivably, since the thicker the electrode pad P, the less likely the underlying layer is to be exposed, the tentative determination threshold (first threshold) related to the area of the needle mark M may be increased. In addition, conceivably, since the lower the strength of (the brittler) the material of the electrode pad P, the more likely a tear or the like of the electrode pad P is to occur, the tentative determination threshold (first threshold) related to the area of the needle mark M may be reduced.

In addition, conceivably, since a tear or the like of the electrode pad P is more likely to occur when the ratio of the area of the needle mark M to the electrode pad P is equal to or greater than a reference value, when portions other than the needle mark M on the electrode pad P are equal to or less than a reference value, when a distance between an end part of the electrode pad P and the needle mark M is equal to or less than a reference value, and the like, a determination of “abnormal” (fail) may be tentatively made. In this case, each reference value may be adjusted according to the strength of the material of the electrode pad P and, for example, the lower the strength of (the brittler) the material of the electrode pad P, the stricter the criteria for tentatively making a determination of “abnormal” (fail) may be.

Next, with respect to the electrode pad P determined as “fail” in the tentative determination (step S16), a quality determination (formal determination) is performed using the 3D shape measuring machine 52 (step S18).

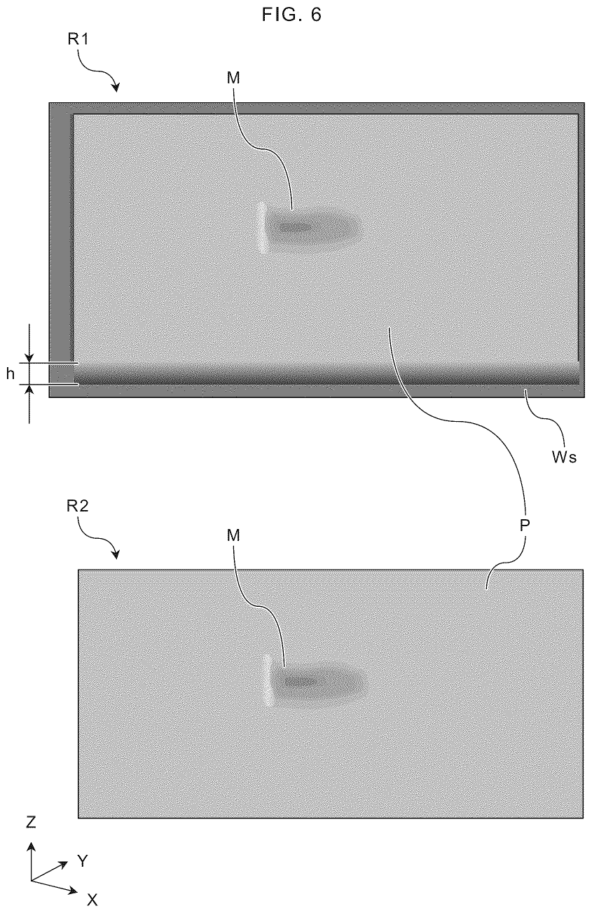

FIG. 6 is a diagram illustrating an example of measured data obtained by measuring the electrode pad P that is an object of a formal determination with the 3D shape measuring machine 52. In FIG. 6, three-dimensional coordinates measured by the 3D shape measuring machine 52 are illustrated stereoscopically by light and dark.

In step S18, first, a measurement of a three-dimensional shape of a region including the electrode pad P tentatively determined as “fail” is performed. In the present embodiment, a positional relationship between the 2D camera 50 and the 3D shape measuring machine 52 is known or calibrated. Therefore, based on the position (coordinates) of the electrode pad P in the captured image IMG by the 2D camera 50, a measurement of the region including the electrode pad P tentatively determined as “fail” can be performed using the 3D shape measuring machine 52.

As illustrated in FIG. 6, measured data R1 by the 3D shape measuring machine 52 includes a measurement result of three-dimensional coordinates (XYZ coordinates) of each position of the region including the electrode pad P having been tentatively determined as “fail” and being an object of a formal determination and, for example, a measurement result of three-dimensional coordinates of a region including a region Ws of a surface of the wafer W (chip C) between the electrode pad P that is the object of the formal determination and an adjacent electrode pad.

The control unit 10 extracts the electrode pad P that is the object of the formal determination from the measured data R1. In the present embodiment, for example, the electrode pad P is extracted based on a difference h between a height (Z coordinate) of the electrode pad P that is the object of the formal determination and a height (Z coordinate) of the region Ws on the surface of the wafer W (chip C) between the electrode pad P and an adjacent electrode pad. Specifically, for example, the control unit 10 extracts a surface region of the electrode pad P by excluding regions that are lower by the thickness than the height (Z coordinate) of the electrode pad P.

Next, the control unit 10 calculates a second feature amount related to the needle mark M from measured data R2 obtained by extracting the surface region of the electrode pad P. In the present embodiment, the maximum pit depth Sv defined by JIS B 0681-2: 2018 or ISO 25178-2: 2012 is used as the second feature amount.

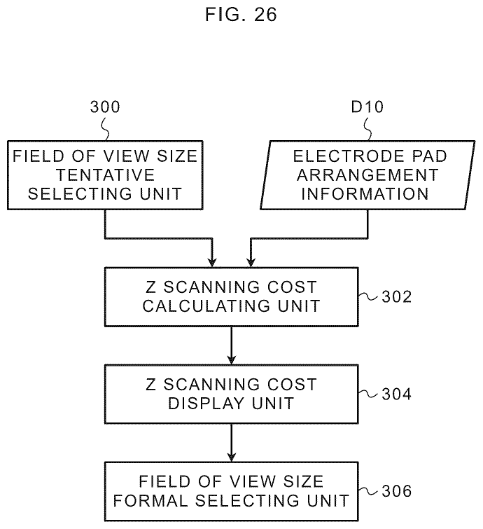

FIG. 26 is a diagram for explaining a feature amount (maximum pit depth Sv) of the needle mark M formed on the electrode pad P. In FIG. 26, a three-dimensional shape (unevenness) of the surface of the electrode pad P is depicted by a curve along the X direction.

The maximum pit depth Sv is an absolute value of a minimum height with respect to an average surface Pm whose height (Z coordinate) is an average value (arithmetic average value) on the surface of electrode pad P. Note that in FIG. 26, Sp denotes a maximum peak height and is a maximum value based on the average surface Pm. In addition, Sz denotes a maximum height indicating a distance from a highest point to a lowest point of the surface of the electrode pad P and satisfies Sz=Sp+Sv.

For example, the control unit 10 makes a formal determination of quality of the electrode pad P based on a relationship between the maximum pit depth Sv and a design value of thickness of the electrode pad P. Specifically, for example, the electrode pad P is determined as “fail” when the maximum pit depth Sv is equal to or larger than the design value of thickness of the electrode pad P or equal to or larger than 90% of the design value.

Note that the formal determination is not limited to the example described above. For example, a formal determination threshold (second threshold) related to the maximum pit depth Sv of the formal determination may be changed based on the thickness of the electrode pad P, a ratio of an area of the needle mark M to the electrode pad P of the electrode pad P, a position, or a strength (brittleness) of the material of the electrode pad P. For example, conceivably, since the thicker the electrode pad P, the less likely the underlying layer is to be exposed, the formal determination threshold (second threshold) related to the maximum pit depth Sv may be set to a value closer to the design value of the thickness of the electrode pad P. In addition, conceivably, since the lower the strength (the brittler) of the material of the electrode pad P, the more likely a tear or the like of the electrode pad P is to occur, the formal determination threshold (second threshold) related to the maximum pit depth Sv may be set to a value smaller than the design value of the thickness of the electrode pad P.

In addition, conceivably, since a tear or the like of the electrode pad P is more likely to occur when the ratio of the area of the needle mark M to the electrode pad P is equal to or greater than a reference value, when portions other than the needle mark M on the electrode pad P is equal to or less than a reference value, when a distance between the end part of the electrode pad P and the needle mark M is equal to or less than a reference value, and the like, a determination of “fail” may be made. In this case, each reference value may be adjusted according to the strength of the material of the electrode pad P and, for example, the lower the strength of (the brittler) the material of the electrode pad P, the stricter the criteria for making a determination of “fail” may be.

In addition, for example, when the area of the needle mark M is used as the first feature amount in the tentative determination, a feature amount that the distance between the end part of the electrode pad P and the needle mark M is equal to or less than a reference value and the second feature amount (maximum pit depth Sv) measured by the 3D shape measuring machine 52 may be used in combination.

Once the wafer-level inspection of the wafer W1 (step S14) and the inspection of the electrode pad P (steps S16 and S18) end, the wafer W1 is unloaded from the stage ST (step S20). In addition, as i=i+1 (No in step S22, step S24), a wafer-level inspection (step S14) of a next wafer W2 and an inspection (steps S16 and S18) of the electrode pad P are performed.

Once the wafer-level inspection of the wafer Wi in the lot that is the inspection object (step S14) and the inspection of the electrode pad P (steps S16 and S18) end by repeating steps S12 to S24 (Yes in step S22), the inspection flow ends.

While the 3D shape measuring machine 52 has an advantage of obtaining information in the Z direction, since the 3D shape measuring machine 52 has one more axis as compared to the 2D camera 50, the speed of measurement slows down. For example, when using a white interference microscope or a device using the focus variation method as the 3D shape measuring machine 52, a high NA (Numerical Aperture) lens with high sensitivity on inclined surfaces is used to acquire three-dimensional shapes. A high-NA lens has a larger magnification, resulting in a narrower measurement field of view. As a result, an area on the wafer W that can be measured by one scan is smaller. Since measuring a large area on the wafer W requires moving the measurement field of view in the XY directions and performing scans in the Z direction multiple times, measurement takes time. On the other hand, in the case of the 2D camera 50, since the constraints in the case of the 3D shape measuring machine 52 described above do not apply, a lens with a wide field of view can be used. In addition, in the case of the 2D camera 50, since there is no need to perform scans in the Z direction, measurement can be performed at high speed.

According to the present embodiment, a quality determination of the electrode pad P using the 2D camera 50 capable of making the quality determination at high speed can be made prior to a quality determination by the 3D shape measuring machine 52 to narrow down objects of a formal determination. As a result, the 3D shape measuring machine 52 can accurately inspect needle marks M formed on the surface of the electrode pad P by a wafer-level inspection and reduce the time required for quality determination.

While the inspection object is the needle marks M formed on the electrode pad P in the present embodiment, the present disclosure is not limited thereto as described earlier. For example, the present embodiment is also applicable to a visual inspection for detecting an inspection object such as a scratch or a foreign object on the wafer W.

For example, when the inspection object is a scratch on the wafer W, the wafer W may be determined to be abnormal if at least one of the following feature amounts exceeds a reference value: a size of the scratch (for example, a maximum dimension or a minimum dimension), a depth of the scratch (for example, the maximum pit depth Sv or the maximum height Sz), the area of the scratch (for example, a percentage of an area of the scratch per unit area of the wafer W), and an arrangement of the scratch (for example, the number of scratches per unit area or the like). Furthermore, instead of the feature amounts described above or in addition to the feature amounts described above, the wafer W may be determined to be abnormal when a distance between the scratch and the device is equal to or less than a reference value.

In addition, when the inspection object is a foreign object, the wafer W may be determined to be abnormal if at least one of the following feature amounts exceeds a reference value: a size of the foreign object (for example, a maximum dimension or a minimum dimension) and an arrangement of the foreign object (for example, the number of foreign objects per unit area or the like). Furthermore, instead of the feature amounts described above or in addition to the feature amounts described above, the quality of the wafer W may be determined based on a type of the foreign object. For example, if the foreign object is estimated to be easily removable by air or the like based on the three-dimensional shape of the foreign object, the wafer W may be determined to be not abnormal regardless of the feature amounts described above.

### Modification of First Embodiment

While the tentative determination using the 2D camera 50 and the formal determination using the 3D shape measuring machine 52 are performed in order for each wafer in the first embodiment, an order of inspections of the wafer W is not limited thereto. For example, first, a tentative determination using the 2D camera 50 may be made for one lot, and then a formal determination using the 3D shape measuring machine 52 may be made for wafers W that contain electrode pads P determined as abnormal in the tentative determination.

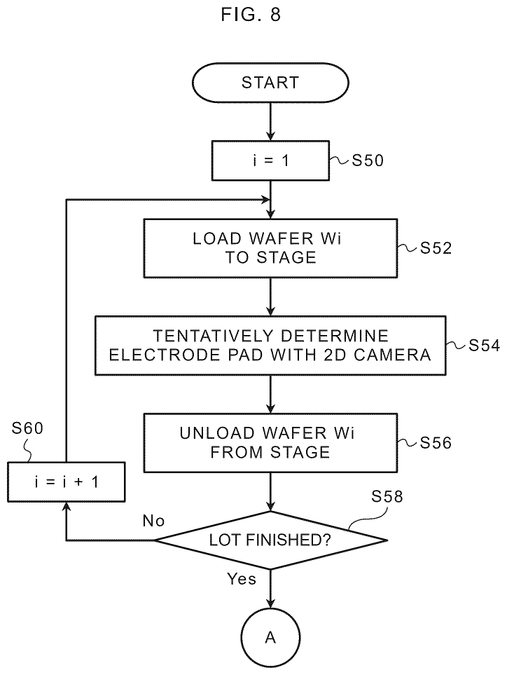

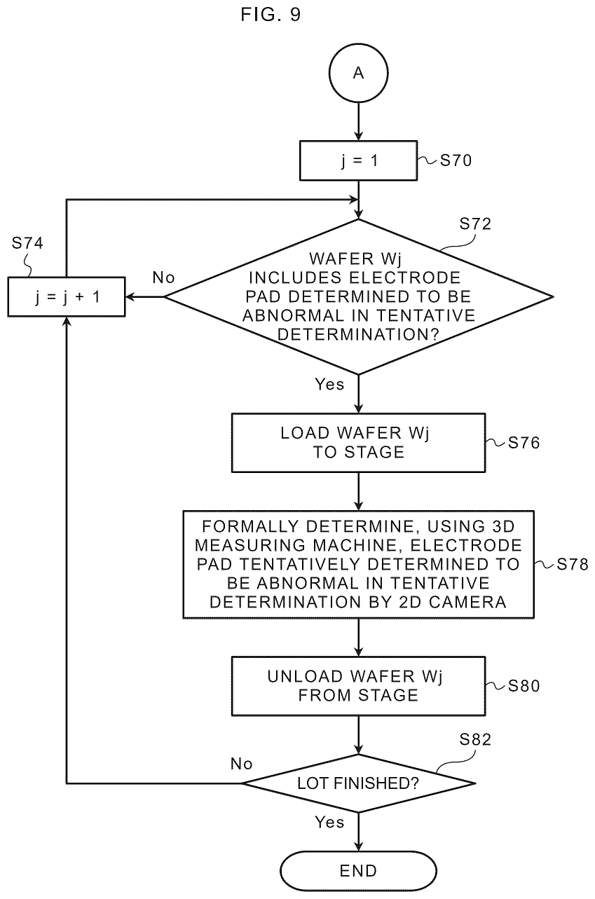

FIGS. 8 and 9 are a flowchart illustrating an inspection method according to a modification of the first embodiment. FIG. 8 is a flowchart of the tentative determination using the 2D camera 50 and FIG. 9 is a flowchart of the formal determination using the 3D shape measuring machine 52.

When the tentative determination of a lot of wafers W is started, as illustrated in FIG. 8, a parameter i of the number of wafers W that are inspection objects is set to i=1 (step S50). In addition, the first wafer W1 is loaded to the stage ST (step S52), and a quality determination (tentative determination) of the electrode pad P is performed using the 2D camera 50 (step S54).

Once the tentative determination (step S54) ends, the wafer W1 is unloaded from the stage ST (step S56). In addition, as i=i+1 (No in step S58, step S60), the tentative determination (step S54) is performed with respect to a next wafer W2.

Once the tentative determination (step S54) of the wafers Wi in the lot that is the inspection object ends by repeating steps S52 to S60 (Yes in step S58), the tentative determination flow ends.

Next, when the formal determination of the lot of wafers W is started, as illustrated in FIG. 9, a parameter j of the number of wafers W that are inspection objects is set to j=1 (step S70). In addition, when the first wafer W1 does not include the electrode pad P having been determined to be abnormal in the tentative determination (No in step S72), the object of the formal determination is changed as j=j+1 (step S74).

On the other hand, when the first wafer W1 includes the electrode pad P having been determined to be abnormal in the tentative determination (Yes in step S72), the wafer W1 is loaded to the stage ST (step S76), and a quality determination (formal determination) of the electrode pad P is performed using the 3D shape measuring machine 52 (step S78).

Once the formal determination (step S78) ends, the wafer W1 is unloaded from the stage ST (step S80). In addition, as j=j+1 (No in step S82, step S74), the tentative determination (steps S72 to S82) is performed with respect to the next wafer W2.

Once the tentative determination (steps S72 to S82) of the wafers Wj in the lot that is the inspection object end by repeating steps S72 to S82 (Yes in step S82), the formal determination flow ends.

Even in the modification, performing a quality determination of the electrode pad P using the 2D camera 50 prior to a quality determination by the 3D shape measuring machine 52 enables an inspection of the needle mark M formed on the surface of the electrode pad P to be performed accurately and at high speed.

Note that FIGS. 8 and 9 do not include a step of a wafer-level inspection and illustrate procedures of a case where an inspection of the electrode pad P is performed after the wafer-level inspection. The present disclosure is not limited thereto and a wafer-level inspection may be included in the flow illustrated in FIGS. 8 and 9 (for example, between steps S52 and S54 in FIG. 8).

### Second Embodiment

The first embodiment is premised on the positional relationship between the 2D camera 50 and the 3D shape measuring machine 52 being known or calibrated. In contrast, in the present embodiment, positioning (alignment) of the 2D camera 50 and the 3D shape measuring machine 52 is performed.

In other words, in the present embodiment, the control unit 10 performs an alignment of the 2D camera 50 and the 3D shape measuring machine 52 after the wafer-level inspection (step S14) and before the inspection of the electrode pad P (steps S16 and S18). In this case, the control unit 10 is an example of the alignment unit.

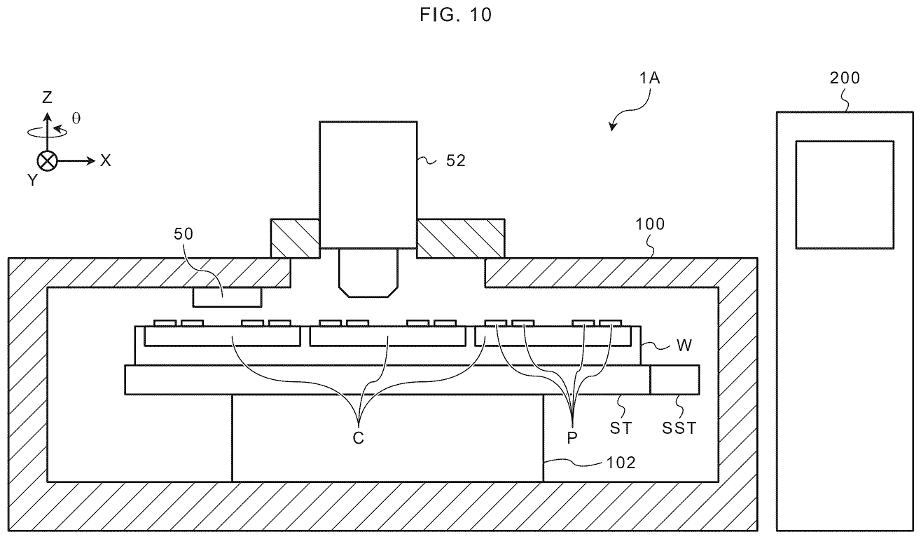

FIG. 10 is a diagram (during wafer-level inspection) illustrating an inspection device according to a second embodiment of the present disclosure. As illustrated in FIG. 10, in an inspection device 1A according to the present embodiment, a substage SST coupled to the stage ST is provided and an alignment mark MA is formed on the substage SST.

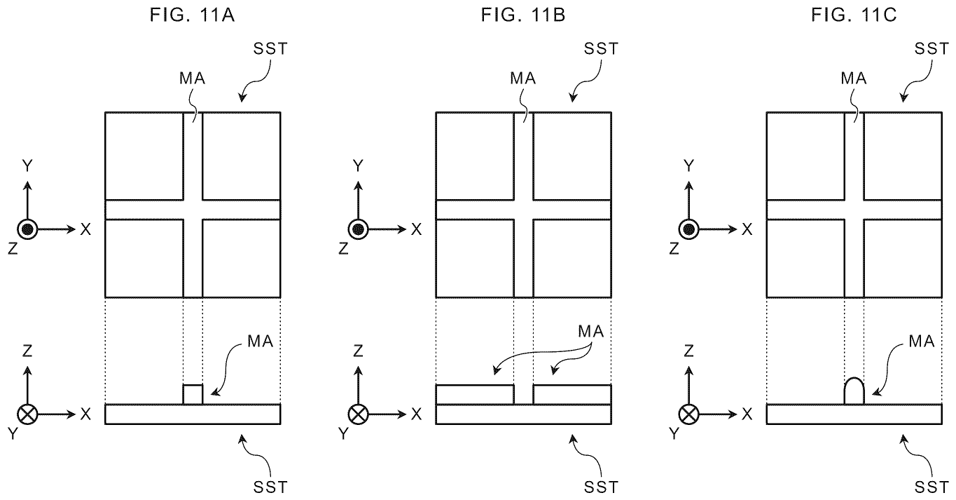

FIGS. 11A to 11C each include a plan view and a front view illustrating examples of the alignment mark MA. FIGS. 11A to 11C illustrate three examples of the alignment mark MA. Note that coordinate axes illustrated in a lower left corner of FIGS. 11A to 11C represent a coordinate system with respect to the inspection device 1A (stage ST).

As illustrated in FIGS. 11A to 11C, the alignment mark MA according to the present embodiment is a cross shape made up of two orthogonal line segments in the XY plane and has a step in the Z direction.

In this case, the alignment mark MA and the substage SST to be an underlay are desirably made of different materials.

In an example illustrated in FIG. 11A, the cross-shaped portion of the alignment mark MA protrudes from the surface of the substage SST and a cross-sectional shape of the protruding portion is rectangular. On the other hand, in an example illustrated in FIG. 11B, the cross-shaped portion of the alignment mark MA is caved into the surface of the substage SST and a cross-sectional shape of the caved-in portion is rectangular. Note that the cross-sectional shape of the caved-in portion may be rounded in FIG. 11B. In addition, in an example illustrated in FIG. 11C, while the cross-shaped portion of the alignment mark MA protrudes from the surface of the substage SST in a similar manner to FIG. 11A, a shape of a tip of the protruding portion is rounded. All of the examples are applicable to the alignment of the 2D camera 50 and the 3D shape measuring machine 52.

Although the shape of the alignment mark MA is a cross shape in the examples illustrated in FIGS. 11A to 11C, the alignment mark MA is not limited thereto. For example, the alignment mark MA may be a shape with components in two independent directions, specifically a rectangle, a rhombus, a triangle, an oval (for example, an ellipse, an elongated circle, or an egg shape), or an L-shape. In addition, since even a circular alignment mark MA can be used by obtaining center coordinates thereof albeit without components in two independent directions, the circular alignment mark MA can be applied to the alignment between the 2D camera 50 and the 3D shape measuring machine 52 according to the present embodiment.

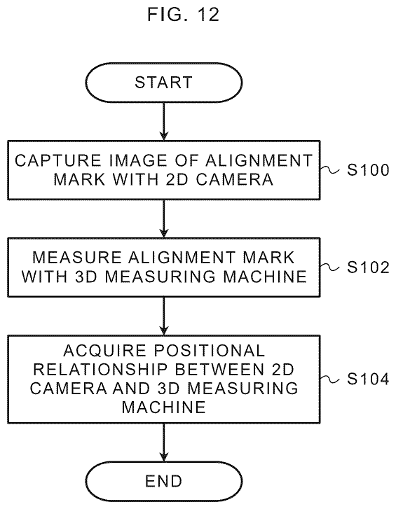

FIG. 12 is a flowchart illustrating procedures of alignment (alignment steps) of the 2D camera 50 and the 3D shape measuring machine 52.

First, the substage SST is moved to below the 2D camera 50 to capture an image of the alignment mark MA (step S100). In step S100, for example, the substage SST is moved to below the 2D camera 50 based on a design value of a position of the substage SST or the like.

Next, XY coordinates (Xs, Ys) of the stage ST are read and an image of the alignment mark MA is captured using the 2D camera 50. At this point, when the 2D camera 50 is a color camera, the image may be converted into a grayscale image.

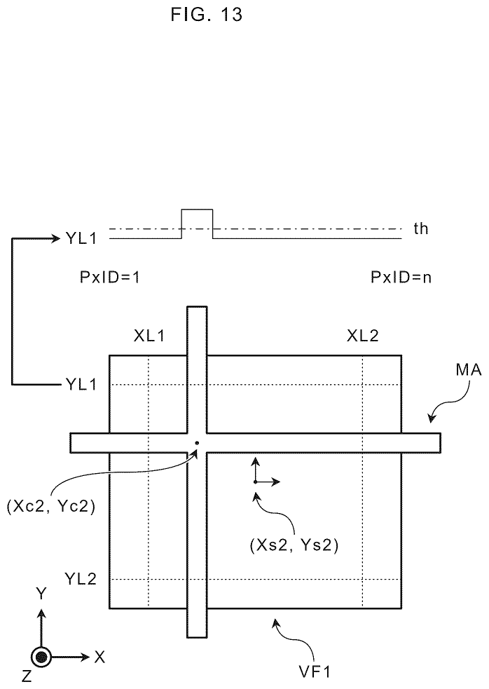

FIG. 13 is a diagram illustrating an example of a captured image of the alignment mark MA. Note that coordinate axes illustrated in a lower left corner of FIG. 13 represent a coordinate system with respect to the inspection device 1A (stage ST).

In FIG. 13, VF1 denotes a field of view of the 2D camera 50, and a center of the field of view VF1 in the coordinate system of the stage ST is (Xs2, Ys2). Note that a center of the field of view VF1 in a visual field coordinate system of the 2D camera 50 is (0, 0). In addition, the number of pixels in the X direction of the field of view VF1 is denoted by n.

As illustrated in FIG. 13, the alignment mark MA is extracted from the captured image at a given cross-section (for example, X=XL1, XL2, Y=YL1, YL2, or the like) and the center of the alignment mark MA or, in other words, an intersection of the cross shape (Xc2, Yc2) is calculated.

In the example illustrated in FIG. 13, brightness of the alignment mark MA is brighter than that of the surface of the substage SST. In the cross-section extracted at Y=YL1, a portion where the brightness exceeds a threshold th is detected in correspondence to the position of the alignment mark MA. An average value of pixel positions PxID of the portion where the brightness exceeds the threshold th is obtained and the average value of PxID is multiplied by a coefficient for converting the pixel position PxID into a distance. Accordingly, an X coordinate (X coordinate in the visual field coordinate system of the 2D camera 50) X (YL1) of the center of the alignment mark MA on the cross-section extracted at Y=YL1 is obtained.

As illustrated in FIG. 13, XY coordinates (XY coordinates in the visual field coordinate system of the 2D camera 50) of the center of the alignment mark MA are calculated on cross-sections in the XY directions. In addition, an average value of the XY coordinates is obtained as XY coordinates (XY coordinates in the visual field coordinate system of the 2D camera 50) (Xc2, Yc2) of the center of the alignment mark MA.

The coordinates (Xc2, Yc2) of the center of the alignment mark MA are represented by the following equations. Note that in the following equations, the numbers of cross-sections extracted in the XY directions are denoted by N and M, respectively.

$$Xc 2 = \{ X ( YL 1 ) + X ( YL 2 ) + X ( YL 3 ) + … + X ( YLN ) \} / N$$

$$Yc 2 = \{ Y ( XL 1 ) + Y ( XL 2 ) + Y ( XL 3 ) + … + Y ( XLM ) \} / M$$

Note that in the example illustrated in FIG. 13, the cross-section to be extracted is desirably extracted at a position around 20% from the edge of the field of view VF.

Next, a position of the alignment mark MA in a coordinate system of the stage ST is obtained. The position of the center of the alignment mark MA in the coordinate system of the stage ST is (Xc2+Xs2, Yc2+Ys2).

Next, the substage SST is moved to below the 3D shape measuring machine 52 to measure the alignment mark MA (step S102). In step S102, a shape of the alignment mark MA is measured and the center of the alignment mark MA is obtained in a similar manner to step S100. Note that in step S102, the alignment mark MA is detected using a difference in heights in the Z direction in 3D shape data instead of light and dark of the alignment mark MA. If the XY coordinates of the center of the alignment mark MA in the visual field coordinate system of the 3D shape measuring machine 52 are (Xc3, Yc3) and the center of the field of view of the 3D shape measuring machine 52 in the coordinate system of the stage ST is (Xs3, Ys3), the position of the center of the alignment mark MA in the coordinate system of the stage ST is (Xc3+Xs3, Yc3+Ys3).

In the case of the 3D shape measuring machine 52 that uses a method such as focus variation, a 2D image of the alignment mark MA may be acquired using a camera mounted on the 3D shape measuring machine 52 without acquiring 3D shape data, and an alignment may be performed using the 2D image.

Next, a positional relationship between the 2D camera 50 and the 3D shape measuring machine 52 is obtained (step S104).

As described above, positions of the alignment mark MA obtained by the 2D camera 50 and the 3D shape measuring machine 52, respectively, are (Xc2+Xs2, Yc2+Ys2) and (Xc3+Xs3, Yc3+Ys3) in the coordinate system of the stage ST.

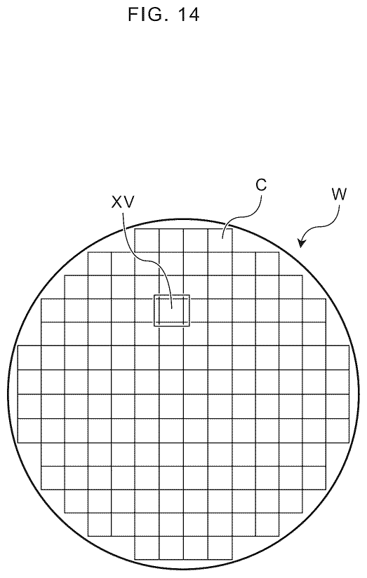

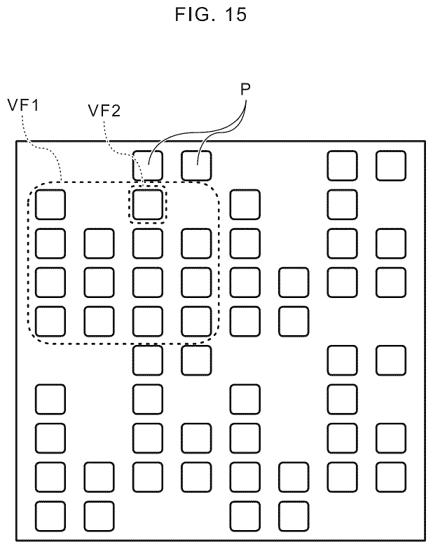

FIGS. 14 and 15 are plan views for explaining a positional relationship between the 2D camera 50 and the 3D shape measuring machine 52. FIG. 15 is an enlarged view of a region XV in FIG. 14. In FIG. 15, fields of view of the 2D camera 50 and the 3D shape measuring machine 52 are denoted by VF1 and VF2, respectively.

Suppose the position of the electrode pad P measured by the 2D camera 50 is (Xpn, Ypn) in the coordinate system of the stage ST. In this case, the position of the 3D shape measuring machine 52 as viewed from the 2D camera 50 is (Xc3+Xs3−Xc2−Xs2, Yc3+Ys3−Yc2−Ys2).

Therefore, the position of the electrode pad P measured by the 2D camera 50 or, in other words, (Xpn, Ypn) in the coordinate system of the stage ST may be measured by the 3D shape measuring machine 52 as (Xpn+Xc3+Xs3−Xc2−Xs2, Ypn+Yc3+Ys3−Yc2−Ys2) in the coordinate system of the stage ST.

Here, a transformation from the coordinate system of the 2D camera 50 to the coordinate system of the stage ST is as follows. The electrode pad P at the position of (Xp2, Yp2) in the coordinate system of the 2D camera 50 is (Xpn, Ypn)=(Xs2+Xp2, Ys2 +Yp2) in the coordinate system of the stage ST.

In the inspection device 1A, the positional relationship between the 2D camera 50 and the 3D shape measuring machine 52 may fluctuate due to a drift of the 2D camera 50 or the 3D shape measuring machine 52 attributable to temperature changes. According to the present embodiment, accuracy of inspection of the electrode pad P can be improved by performing positioning of the 2D camera 50 and the 3D shape measuring machine 52.

Note that a cycle of implementation of the alignment according to the present embodiment is not particularly limited to each wafer W or each lot that is an inspection object. A timing of implementation of the alignment can be determined based on, for example, a degree of drift attributable to environment (temperature changes).

In addition, while the substage SST on which the alignment mark MA is formed is coupled to the stage ST in the present embodiment, the present disclosure is not limited thereto. For example, the alignment mark MA described above may be provided on the wafer W to be applied to the alignment of the 2D camera 50 and the 3D shape measuring machine 52.

### Third Embodiment

In the second embodiment, the alignment mark MA is provided for the alignment of the 2D camera 50 and the 3D shape measuring machine 52. In contrast, in the third embodiment, an alignment of the 2D camera 50 and the 3D shape measuring machine 52 is performed without using the alignment mark MA.

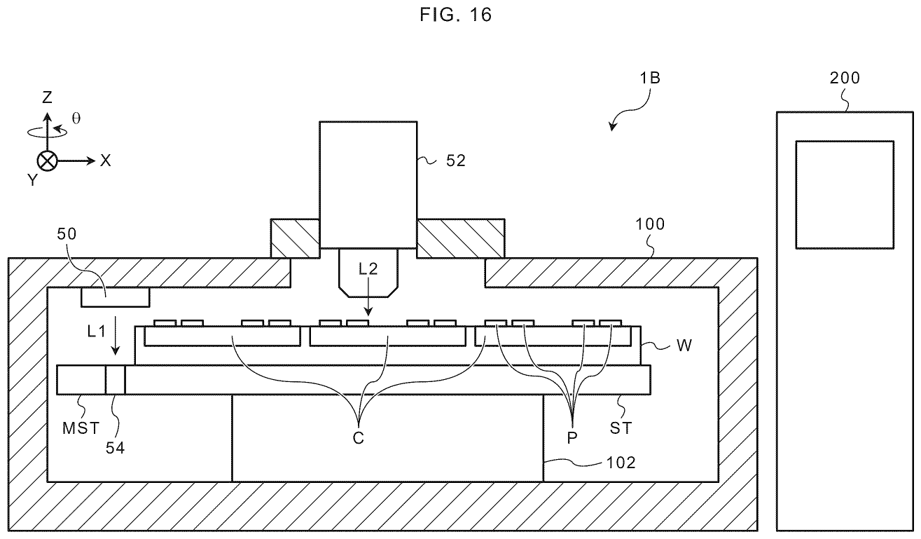

FIG. 16 is a diagram (during wafer-level inspection) illustrating an inspection device according to a third embodiment of the present disclosure.

As illustrated in FIG. 16, in an inspection device 1B according to the present embodiment, the needle alignment camera 54 and a mirror stage MST with a mirror formed on an upper surface thereof are both coupled to an end part of the stage ST.

In the present embodiment, a positional relationship between the 2D camera 50 and the 3D shape measuring machine 52 is obtained by using the needle alignment camera 54 to detect beams output from the 2D camera 50 and the 3D shape measuring machine 52.

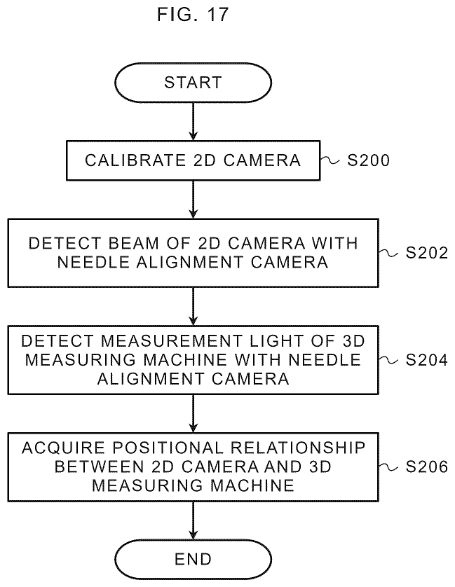

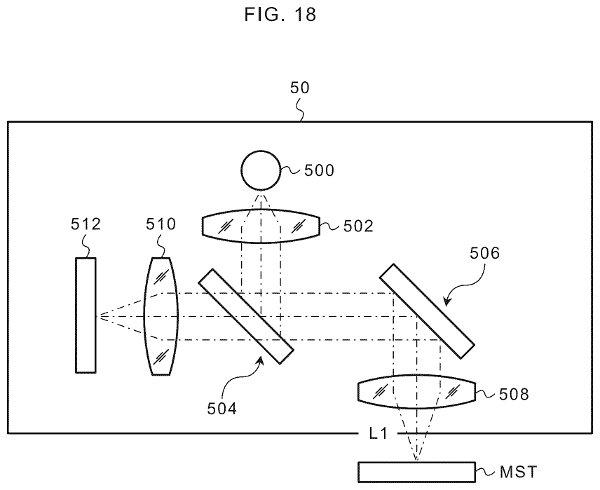

FIG. 17 is a flowchart illustrating procedures of alignment of the 2D camera 50 and the 3D shape measuring machine 52. FIG. 18 is a block diagram illustrating an example of the 2D camera 50.

First, calibration of the 2D camera 50 is performed (step S200). In step S200, an attachment error and the like of a light source 500, an imaging element 512 (refer to FIG. 18), and the like attributable to temperature changes of the inspection device 1B and an installation environment thereof are measured and calibrated.

In step S200, first, the mirror stage MST is moved under the 2D camera 50 and a beam L1 is output toward the mirror stage MST from the light source 500 mounted on the 2D camera 50. The beam output from the light source 500 is collimated by a collimating lens 502, sequentially reflected by a one-way mirror 504 and a mirror 506, and focused by a focusing lens 508 to reach the mirror stage MST. The reflected light from the mirror stage MST travels via the focusing lens 508 and the mirror 506, passes through the one-way mirror 504, and is focused on the imaging element 512 by a focusing lens 510. In this manner, the beam L1 reflected by the upper surface of the mirror stage MST is detected by the imaging element 512 of the 2D camera 50.

Note that an optical system of the 2D camera 50 is not limited to the example illustrated in FIG. 18 and, for example, the mirror 506 may be omitted.

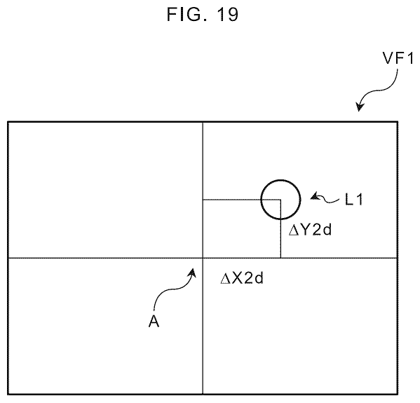

Suppose that the beam L1 is visible at a position of (ΔX2d, ΔY2d) in the coordinate system of the 2D camera 50 in step S200 (refer to FIG. 19).

Next, the stage ST is moved so that a focal point of the beam L1 from the 2D camera 50 can be observed at a center of the field of view of the needle alignment camera 54 and coordinates of the beam L1 are detected (step S202). In this case, a size of the field of view of the needle alignment camera 54 is assumed to be sufficiently larger than a spot diameter of the beam L1 mounted on the 2D camera 50 and sufficiently larger than a spot diameter of measurement light of the 3D shape measuring machine 52.

In a coordinate system of the needle alignment camera 54, a position of the beam L1 is expressed as (ΔXp1, ΔYp1) and a position of the stage ST at this point is expressed as (Xs1, Ys1). In this case, a center A of a field of view VF1 of the 2D camera 50 in the coordinate system of the stage ST is expressed by the following equation.

A=(Xs1−ΔX2d−ΔXp1, Ys1−ΔY2d−ΔYp1)

Next, the stage ST is moved so that measurement light L2 (for example, white light of white interference microscope or the like) from the 3D shape measuring machine 52 can be observed at the center of the field of view of the needle alignment camera 54 and coordinates of the measurement light L2 are detected (step S204). In the coordinate system of the needle alignment camera 54, a beam position of the 3D shape measuring machine 52 is expressed as (ΔXp2, ΔYp2) and a position of the stage ST at this point is expressed as (Xs2, Ys2). In this case, a position B of the 3D shape measuring machine 52 in the coordinate system of the stage ST is expressed by the following equation.

$$B = ( Xs 2 - Δ Xp 2 , Ys 2 - Δ Yp 2 )$$

Next, a positional relationship between the 2D camera 50 and the 3D shape measuring machine 52 is obtained (step S206). The position of the 3D shape measuring machine 52 with respect to the 2D camera 50 is B-A.

Even in the inspection device 1B, the positional relationship between the 2D camera 50 and the 3D shape measuring machine 52 fluctuates due to a drift of the 2D camera 50 or the 3D shape measuring machine 52 attributable to temperature changes. According to the present embodiment, accuracy of inspection of the electrode pad P can be improved by performing positioning of the 2D camera 50 and the 3D shape measuring machine 52.

Note that a cycle of implementation of the alignment according to the present embodiment is also not particularly limited to each wafer W or each lot that is an inspection object in a similar manner to the second embodiment. A timing of implementation of the alignment can be determined based on, for example, a degree of drift attributable to environment (temperature changes).

Note that when the center A of the field of view VF1 of the 2D camera 50 and the focal point position of the beam L1 have already been calibrated, calibration using the mirror stage MST (step S200) can be omitted.

In addition, when the 3D shape measuring machine 52 is provided with an external light source for alignment beams, an alignment can be performed in a similar manner to the third embodiment by using the light source.

### Fourth Embodiment

In the present embodiment, while a case where detection of needle marks formed on an electrode pad P of a wafer W is performed after a wafer-level inspection will be described as an example of a visual inspection of a wafer, the present disclosure is not limited thereto. For example, the present embodiment is also applicable to a measurement (detection) of any inspection object (for example, a scratch or a foreign object) on the wafer W.

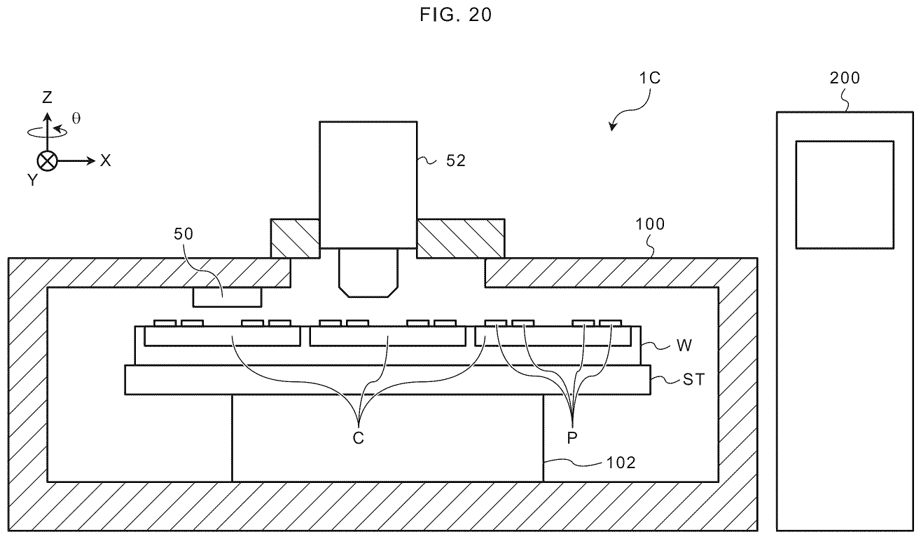

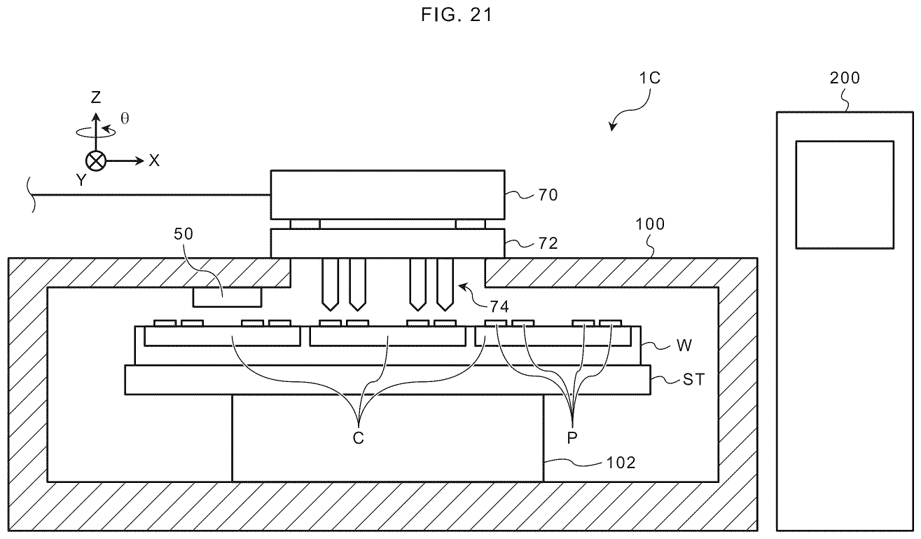

FIGS. 20 and 21 are diagrams illustrating an inspection device according to a fourth embodiment of the present disclosure. FIG. 21 illustrates a state upon execution of a wafer-level inspection, and FIG. 20 illustrates a state upon inspection (detection of needle marks) of the electrode pad P of the wafer W after the wafer-level inspection.

Upon execution of the wafer-level inspection, as illustrated in FIG. 21, the test head 70 is attached to a housing of the measurement unit 100 of an inspection device 1C. Next, the probe needle 74 of the probe card 72 is brought into contact with the electrode pad P formed on a surface of the wafer W that is an inspection object and a test signal is supplied. A signal output by the semiconductor device (chip C) in response to the test signal is then measured by a tester to electrically inspect whether the semiconductor device operates normally. In the wafer-level inspection, a part of an oxide film on a surface of the electrode pad P is scraped off by the probe needle 74 and the probe needle 74 and the electrode pad P become conductive.

Upon inspection of the electrode pad P of the wafer W, as illustrated in FIG. 20, a three-dimensional shape measuring machine (hereinafter, referred to as a “3D shape measuring machine”) 52 is attached to the measurement unit 100 of the inspection device 1C.

In the inspection of the electrode pad P of the wafer W, first, an image of the chip C is captured using a 2D camera (for example, an imaging unit for alignment of the wafer W) 50, and electrode pad arrangement information including information related to an arrangement of the electrode pad P in an XY plan view is acquired.

Next, based on the arrangement information of the electrode pad P described above, inspection conditions for an inspection of the electrode pad P using the 3D shape measuring machine 52 are set. Specifically, for example, (A) a scanning speed in the height direction (Z direction) is set, (B) a field of view size of the 3D shape measuring machine 52 is set, (C) a measurement order of the electrode pad P is set, or the like.

Next, according to the inspection conditions described above, an inspection of the electrode pad P using the 3D shape measuring machine 52 is performed. The 3D shape measuring machine 52 is a device for measuring a three-dimensional shape of the electrode pad P without coming into contact with the surface of the electrode pad P. A measurement method employed by the 3D shape measuring machine 52 is not particularly limited and examples of measurement methods that can be applied include white light interferometry, SD-OCT (Spectral Domain Optical Coherence Tomography), FD-OCT (Fourier Domain Optical Coherence Tomography), a laser confocal method, a triangulation method, an optical cutting method, a pattern projection method, an optical comb method, and a focus variation method. In addition, as the 3D shape measuring machine 52 using white light interferometry, for example, the 3D shape measuring machine described in Japanese Patent Application Laid-Open No. 2016-080564 or Japanese Patent Application Laid-Open No. 2016-161312 can be applied.

In the inspection of the electrode pad P, a three-dimensional shape of the electrode pad P is measured using the 3D shape measuring machine 52, and a feature amount of the electrode pad P (for example, a maximum pit depth Sv of the needle mark formed in the electrode pad P) is obtained. In this case, the maximum pit depth Sv is a parameter defined by JIS (Japanese Industrial Standards) B 0681-2: 2018 or ISO (International Organization for Standardization) 25178-2: 2012. When the maximum pit depth Sv exceeds a threshold, since it is likely that the underlying layer is exposed by the needle mark and circuitry is damaged, a determination of “abnormal” (fail) is made.

According to the present embodiment, suitably setting inspection conditions for the electrode pad P using the 3D shape measuring machine 52 enables a needle mark formed on the electrode pad P to be inspected accurately and at high speed.

While information related to the arrangement of the electrode pad P is acquired using the 2D camera 50 in the present embodiment, the present disclosure is not limited thereto. For example, the acquisition step using the 2D camera 50 may be omitted using design information of the chip C with respect to the arrangement of the electrode pad P. In addition, an image captured by the 2D camera 50 may be compared with the design information of the chip C, and when a difference between the captured image and the design information is equal to or larger than a threshold, information related to the arrangement of the electrode pad P may be acquired from the image captured by the 2D camera 50.
Configuration of Inspection Device

As illustrated in FIGS. 20 and 21, the inspection device 1C according to the present embodiment includes the measurement unit 100 and the loader unit 200 that supplies and retrieves the wafer W that is an inspection object to and from the measurement unit 100. The measurement unit 100 and the loader unit 200 are separable. Note that although the measurement unit 100 and the loader unit 200 can be provided in plurality, only one each is illustrated for the sake of simplicity of description.

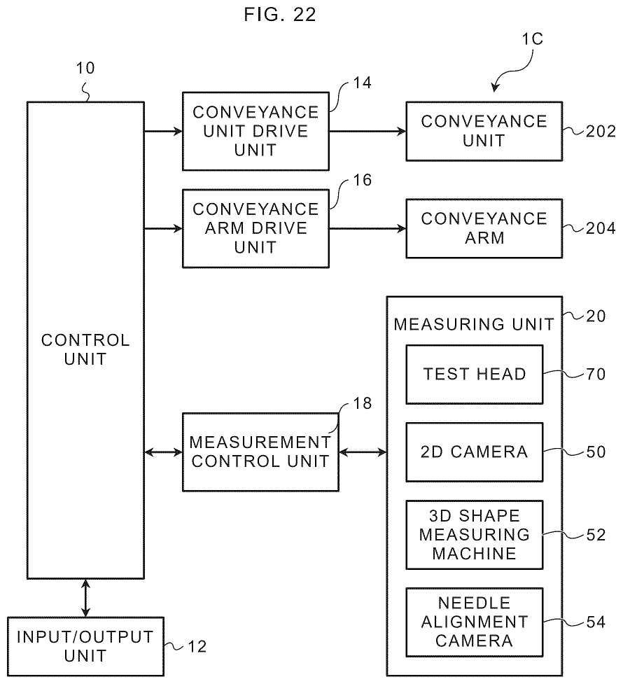

The loader unit 200 has a load port on which a wafer cassette is placed and the conveyance unit 202 (refer to FIG. 22) which conveys the wafer W between each measurement unit 100 of the measurement units 100 and the wafer cassette.

When the wafer W is supplied from the loader unit 200 to each measurement unit 100, the wafer W is held by suction on a holding surface of a stage ST of each measurement unit 100.

The stage movement mechanism 102 supports a lower surface (a surface on an opposite side to the holding surface on which the wafer W is held by suction) of the stage ST. The stage movement mechanism 102 is configured to be movable in XYZ directions and rotatable in a θ direction (a rotation direction around the Z direction). Accordingly, due to the stage movement mechanism 102, the wafer W held by suction on the holding surface of the stage ST is movable in the XYZ directions and rotatable in the θ direction together with the stage ST.

As illustrated in FIG. 21, upon execution of the wafer-level inspection, the test head 70 is attached to the measurement unit 100 of the inspection device 1C.

The probe card 72 is provided at a position opposing the stage ST and arranged approximately parallel to the holding surface of the stage ST. Probe needles 74 are formed on the surface opposing the stage ST of the probe card 72. The probe card 72 is connected to a tester body via the test head 70.

Chips C are formed on the wafer W, and each chip C includes one or more electrode pads P. By moving the stage ST in the XYZ directions or rotating the stage ST in the θ direction with the stage movement mechanism 102, positioning of the wafer W and the probe card 72 is performed so as to bring each probe needle 74 into contact with a corresponding electrode pad P.

After positioning and contact of the probe needle 74 and the electrode pad P by the inspection device 1C, an electric signal is sent to the chip C from the tester body via the test head 70, the probe card 72, and the probe needle 74 to perform an inspection (wafer-level inspection) of electrical characteristics of the chip C on the wafer W. A result of the inspection of electrical characteristics is output by the input/output unit 12 (refer to FIG. 22) in a form that can be checked by an operator.

After the end of the inspection of electrical characteristics of the chip C on the wafer W, the wafer W is conveyed from the inspection device 1C to the loader unit 200 by a conveyance unit to be retrieved.

As illustrated in FIG. 20, the 3D shape measuring machine 52 is attached to the measurement unit 100 of the inspection device 1C during the inspection of the electrode pad P of the wafer W. In addition, needle marks formed in the electrode pad P by the wafer-level inspection are sequentially detected by the 3D shape measuring machine 52 to perform quality determination of the needle marks formed on the electrode pad P.

While the 2D camera 50 and the 3D shape measuring machine 52 are separately attached in the present embodiment, the present disclosure is not limited thereto. For example, the 2D camera 50 and the 3D shape measuring machine 52 may be made interchangeable by a revolver mechanism.

Furthermore, while the test head 70 and the 3D shape measuring machine 52 are attachable to and detachable from the measurement unit 100 of the inspection device 1C in the present embodiment, the present disclosure is not limited thereto. For example, a wafer-level inspection and an inspection of the electrode pad P after the wafer-level inspection may be performed by different devices.

In addition, the test head 70, the 2D camera 50, the 3D shape measuring machine 52, and the like and the stage ST need only be relatively movable, and the test head 70, the 2D camera 50, the 3D shape measuring machine 52, and the like may be made movable with respect to the stage ST.

### Control System of Inspection Device

FIG. 22 is a block diagram illustrating a control system of the inspection device according to the fourth embodiment of the present disclosure.

As illustrated in FIG. 22, the inspection device 1C according to the present embodiment includes the control unit 10, the input/output unit 12, the conveyance unit drive unit 14, the conveyance arm drive unit 16, and the measurement control unit 18.

The control unit 10 includes a processor (for example, a CPU (Central Processing Unit) or an MPU (Micro Processor Unit)), a ROM (Read Only Memory), a RAM (Random Access Memory), and a storage device (for example, an HDD (Hard Disk Drive) or an SSD (Solid State Drive)). In the control unit 10, functions of various units of the inspection device 1C are realized by the processor by executing various programs such as a control program stored in the storage device.

The input/output unit 12 includes a display unit (for example, a liquid crystal display) that displays a GUI (Graphical User Interface) or the like for operating the inspection device 1C and an operating unit (for example, a touch panel, a keyboard, or a pointing device) for receiving operation input from an operator.

The conveyance unit drive unit 14 includes a motor or the like for moving the conveyance unit 202 in the XYZ directions and rotating the conveyance unit 202 in the θ direction (around the Z direction) inside the loader unit 200.

The conveyance arm drive unit 16 includes a motor for extending and contracting the conveyance arm 204 attached to the conveyance unit 202 in a length direction of the conveyance arm 204 and a control valve for suctioning the wafer W to a suction hole of the conveyance arm 204. The control valve is connected to a vacuum (pump) provided at an installation side of the inspection device 1C.

The control unit 10 controls the conveyance unit 202 and the conveyance arm 204 by the conveyance unit drive unit 14 and the conveyance arm drive unit 16, respectively, to retrieve the wafer W from wafer cassettes and to carry the wafer W into and out from the measurement units 100.

The needle alignment camera 54 is a device for detecting a tip position of the probe needle 74 and is provided on, for example, the stage ST. The control unit 10 performs positioning of the probe needle 74 and the electrode pad P based on a detection result of the tip position of the probe needle 74 and a detection result of the electrode pad P by the 2D camera 50.

The measurement control unit 18 performs, according to a control signal from the control unit 10, drive control of the test head 70 for inspection of the wafer W provided in the measurement unit 100, imaging control of the 2D camera 50, measurement control of the 3D shape measuring machine 52, and imaging control of the needle alignment camera 54. As the test head 70 and the 2D camera 50, for example, the test head and the 2D camera described in Japanese Patent Application Laid-Open No. 2019-102591 can be used.

### Setting Inspection Conditions

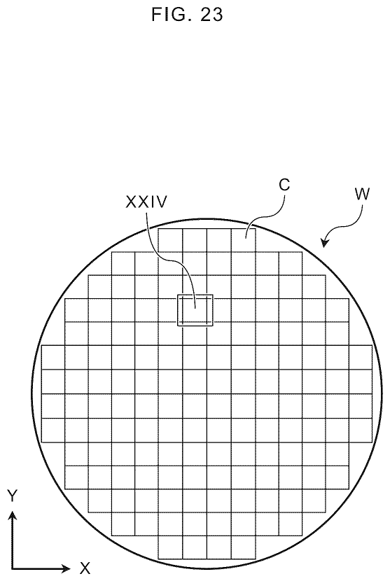

Next, a procedure for setting inspection conditions will be described. FIG. 23 is a plan view of the wafer W. As illustrated in FIG. 23, chips C are formed on a surface of the wafer W, and an electrode pad P is formed on each of the chips C.

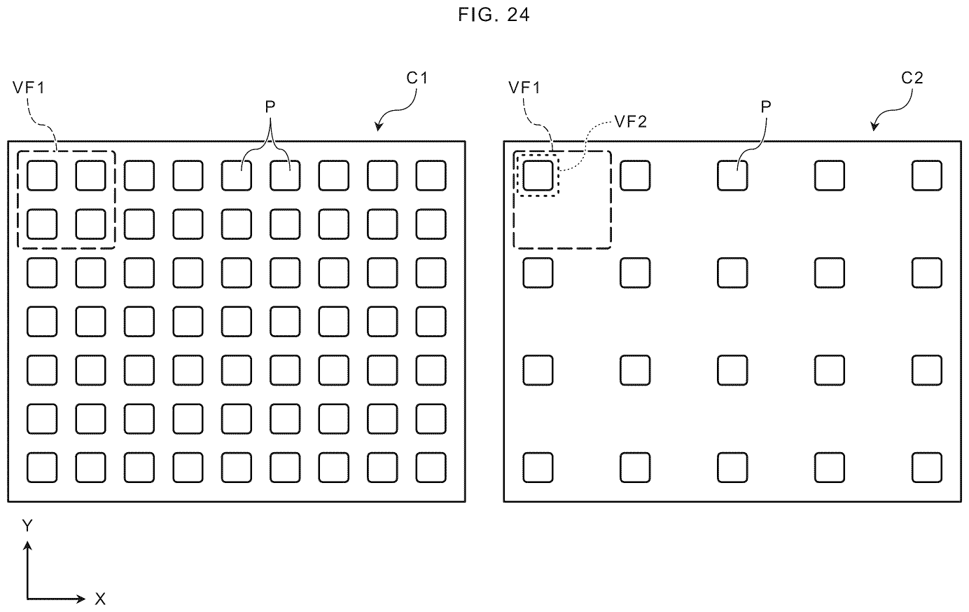

FIG. 24 is an enlarged plan view of the chip C (region XXIV in FIG. 23). C1 in FIG. 24 denotes an example of a chip in which a density of electrode pads P per unit area (number density) is high, and C2 in FIG. 24 denotes an example in which the density of electrode pads P per unit area is low.

In example C1 in which the density of electrode pads P is high, a plurality of (four in example C1) electrode pads P can be included in the measurement field of view VF1 of the 3D shape measuring machine 52. In this case, a single scan in the Z direction by the 3D shape measuring machine 52 can collectively measure the electrode pads P in the measurement field of view VF1.

On the other hand, in example C2 in which the density of electrode pads P is low, only one electrode pad P can be included in the measurement field of view VF1 of the 3D shape measuring machine 52. In this case, as designated by reference character VF2, the measurement field of view is set narrow to match the electrode pad P. Setting the measurement field of view narrow enables a scanning speed in the Z direction by the 3D shape measuring machine 52 to be increased. In addition, since narrowing the measurement field of view results in narrowing a measurement range of a 3D shape and reducing an amount of measured data to be processed, time required to analyze the 3D shape can be reduced.

As described above, the greater the number of electrode pads P that can be included in the measurement field of view of the 3D shape measuring machine 52 (the wider the measurement field of view), the fewer the number of scans in the Z direction. On the other hand, the narrower the measurement field of view of the 3D shape measuring machine 52, the less time is required for scanning in the Z direction and analyzing the 3D shape.

Hereinafter, (A) scanning speed in the Z direction and (B) size of measurement field of view (field of view range PA) among the inspection conditions will be described in specific terms.

When relatively scanning in the Z direction with respect to the wafer W, the 3D shape measuring machine 52 performs imaging in response to a trigger signal output for each predetermined scale (interval). If the scanning speed of the 3D shape measuring machine 52 with respect to the wafer W is denoted by V_{C} (nm/s) and a sampling interval of the 3D shape measuring machine 52 is denoted by D_{C} (nm), a sampling frequency of the 3D shape measuring machine 52 denoted by F_{S} (Hz) is expressed by the following equation.

$${F}_{S} = {V}_{C} / {D}_{C} \qquad ( 1 )$$

The sampling frequency F_{S} of the 3D shape measuring machine 52 is the number of observation images photographed per second when the 3D shape measuring machine 52 photographs observation images based on the trigger signal.

A maximum frame rate F_{C} [fps] which is a maximum value of the number of frames (captured images) that can be photographed by the 3D shape measuring machine 52 in one second and a field of view range PA of the 3D shape measuring machine 52 are usually roughly inversely proportional to each other, as illustrated in the following equation.

$${F}_{C} \approx A / PA ( A : proportionality coefficient ) \qquad ( 2 )$$

When the sampling frequency F_{S} is higher than the maximum frame rate F_{C} (F_{C}<F_{S}), if photography at a speed exceeding the maximum frame rate F_{C} is instructed, the excess is ignored and a so-called frame drop occurs. An occurrence of a frame drop may cause a decline in measurement accuracy. Therefore, the maximum frame rate F_{C} must be set equal to or higher than the sampling frequency F_{S} (F_{C}≥F_{S}). In practice, the sampling frequency F_{S} is set to F_{S}=α×F_{C} (0<α<1) to account for the effects of vibration and the like.

By substituting F_{S}=α×F_{C} into equations (1) and (2), we get equation (3) below.

$${V}_{C} \approx {D}_{C} \times α \times A / PA \qquad ( 3 )$$

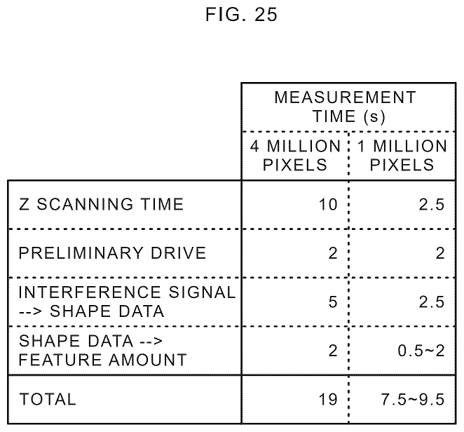

As illustrated in equation (3), the narrower the field of view range PA, the faster the scanning speed V_{C} in the Z direction can be. For example, suppose that the sampling interval D_{C}=20 nm, α=0.1, A=8×10⁹, and the scanning range in the Z direction=40 μm. An example of a measurement time in this case is illustrated in FIG. 25.

As illustrated in FIG. 25, the measurement time is about 19 seconds when the number of pixels in the measurement field of view is 4 million, whereas the measurement time for 1 million pixels is about 7.5 to 9.5 seconds.

When four electrode pads P are to be included in the measurement field of view (example C1), if the measurement field of view is assumed to have 4 million pixels, the measurement time per electrode pad is 19÷4=4.75 seconds/pad. In contrast, when the measurement field of view is 1 million pixels (when the number of pixels allocated per electrode pad is made approximately the same), the measurement time per electrode pad is 7.5 to 9.5 seconds/pad. In other words, when four electrode pads P are to be included in the measurement field of view, it is advantageous to set the measurement field of view to 4 million pixels.

On the other hand, when only one electrode pad P is to be included in the measurement field of view (example C2), if the measurement field of view is assumed to have 4 million pixels, the measurement time per electrode pad is 19 seconds/pad. In contrast, when the measurement field of view is 1 million pixels, the measurement time per electrode pad is 7.5 to 9.5 seconds/pad. In other words, when only one electrode pad P is to be included in the measurement field of view, it is advantageous to set the measurement field of view to 1 million pixels.

By suitably selecting the size of the measurement field of view according to the arrangement and the density of the electrode pads P that are measurement objects as described above, the inspection of the electrode pads P can be accelerated.

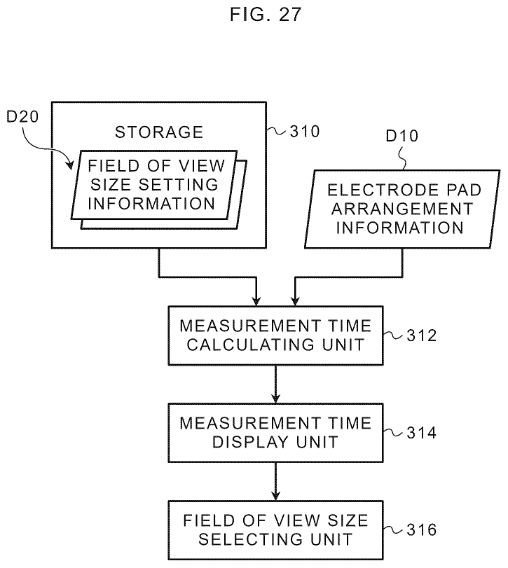

Next, a function of setting inspection conditions (A) and (B) will be described with reference to FIGS. 26 and 27. The function illustrated in FIGS. 26 and 27 is realized by the processor of the control unit 10 by acquiring required data such as electrode pad arrangement information D10 and executing software for realizing the following function. In other words, the control unit 10 is an example of the calculating unit.

FIG. 26 is a block diagram illustrating a function of setting a scanning speed in the Z direction of the 3D shape measuring machine 52 and the wafer W. FIG. 26 illustrates an example of setting an optimum Z-direction scanning speed (measurement time) according to the size of the measurement field of view when measuring electrode pads P.

A field of view size tentative selecting unit 300 tentatively selects a field of view size of the measurement field of view. The tentative selection may be performed by accepting an operation input by the operator via an operating unit of the input/output unit 12 or, for example, automatically selected based on a type of the wafer W (lot) that is an inspection object or the like.

A Z scanning cost calculating unit 302 acquires electrode pad arrangement information D10 including information related to an arrangement of the electrode pad P from an image of the wafer W captured by the 2D camera 50. In addition, the Z scanning cost calculating unit 302 acquires a result of the tentative selection by the field of view size tentative selecting unit 300. Furthermore, based on the electrode pad arrangement information D10 and the result of the tentative selection of the field of view size, the Z scanning cost calculating unit 302 calculates a measurement cost required for scanning in the Z direction (in other words, a scanning speed or a measurement time including the time required for scanning in the Z direction).

As described above, setting the measurement field of view narrow enables a scanning speed in the Z direction by the 3D shape measuring machine 52 to be increased. In addition, since narrowing the measurement field of view results in narrowing a measurement range of a 3D shape and reducing an amount of measured data to be processed, time required to analyze the 3D shape can be reduced.

The Z scanning cost calculating unit 302 calculates the scanning speed or the measurement time including the time required for scanning in the Z direction based on an index correlated to the scanning speed in the Z direction and an index correlated to the size of the measurement field of view. In this case, the index correlated to the scanning speed in the Z direction is, for example, a rotational speed of a motor for relatively moving the 3D shape measuring machine 52 and the wafer W in the Z direction, a current supplied to the motor, a pulse interval of the motor (in a case of PWM (Pulse Width Modulation) control), or the like. Specifically, the narrower the measurement field of view of the 3D shape measuring machine 52, the Z scanning cost calculating unit 302 increases the calculated value of the scanning speed. In addition, the narrower the measurement field of view of the 3D shape measuring machine 52 or the larger the number of electrode pads that can be included in the measurement field of view, the Z scanning cost calculating unit 302 reduces the calculated value of the measurement time.

A Z scanning cost display unit 304 outputs a calculation result by the Z scanning cost calculating unit 302 to a display unit of the input/output unit 12. Accordingly, the operator can check the scanning speed or the measurement time in the Z direction corresponding to the tentatively selected field of view size of the measurement field of view. In addition, by accepting an operation input from the operator via the input/output unit 12, the tentative selection of the field of view size of the measurement field of view can be changed and the scanning speed or the measurement time in the Z direction can be caused to be recalculated. In other words, the operator can select (formally select) the scanning speed or the measurement time in the Z direction in a form of trial and error while referring to a result of the recalculation.

A field of view size formal selecting unit 306 selects (formally selects) the scanning speed or the measurement time in the Z direction by accepting an operation input from the operator via the input/output unit 12.

Note that while the operator performs the formal selection via the input/output unit 12 in the present embodiment, the present disclosure is not limited thereto. For example, calculations may be performed by the control unit 10 with respect to the electrode pad arrangement information and all patterns of sizes of the measurement field of view (for example, patterns already registered in the inspection device 1C), and the size of the measurement field of view with the shortest measurement time may be automatically selected as a result of the calculations. In addition, the control unit 10 may sequentially perform calculations for each pattern of the sizes of the measurement field of view based on the electrode pad arrangement information, and automatically select the size of the measurement field of view at a time point where the measurement time (measurement cost) becomes equal to or lower than a reference value. In other words, the control unit 10 may automatically select a size of the measurement field of view that enables measurement cost to satisfy a predetermined criterion (for example, the measurement time being the shortest among results calculated for all patterns or the measurement time being equal to or lower than a reference value).

FIG. 27 is a block diagram illustrating a function of setting a size of the measurement field of view of the 3D shape measuring machine 52.

As illustrated in FIG. 27, a storage 310 of the control unit 10 stores different types of field of view size setting information D20 in advance. The field of view size setting information D20 may be registered in advance to the storage 310 by a manufacturer of a prober or the inspection device 1C, the operator, a manager of the operator, or the like.

A measurement time calculating unit 312 acquires electrode pad arrangement information D10 including information related to an arrangement of the electrode pad P from an image of the wafer W captured by the 2D camera 50. In addition, the measurement time calculating unit 312 reads the field of view size setting information D20 from the storage 310. The measurement time calculating unit 312 calculates the measurement time for each piece of field of view size setting information D20 based on the electrode pad arrangement information D10. The measurement time calculating unit 312 calculates the measurement times based on an index correlated to the scanning speed in the Z direction and an index correlated to the size of the measurement field of view. Specifically, the narrower the measurement field of view of the 3D shape measuring machine 52, the measurement time calculating unit 312 increases the calculated value of the scanning speed. In addition, the narrower the measurement field of view of the 3D shape measuring machine 52 or the larger the number of electrode pads that can be included in the measurement field of view, the measurement time calculating unit 312 reduces the calculated value of the measurement time.

A measurement time display unit 314 outputs a calculation result by the measurement time calculating unit 312 to the display unit of the input/output unit 12. Accordingly, the operator can check the measurement time for each piece of field of view size setting information D20.

As described above, the greater the number of electrode pads P that can be included in the measurement field of view of the 3D shape measuring machine 52 (the wider the measurement field of view), the fewer the number of scans in the Z direction and the shorter the measurement time. In addition, since narrowing the measurement field of view results in narrowing a measurement range of a 3D shape and reducing an amount of measured data to be processed, time required to analyze the 3D shape can be reduced.

A field of view size selecting unit 316 selects the field of view size of the measurement field of view by accepting an operation input from the operator via the input/output unit 12.

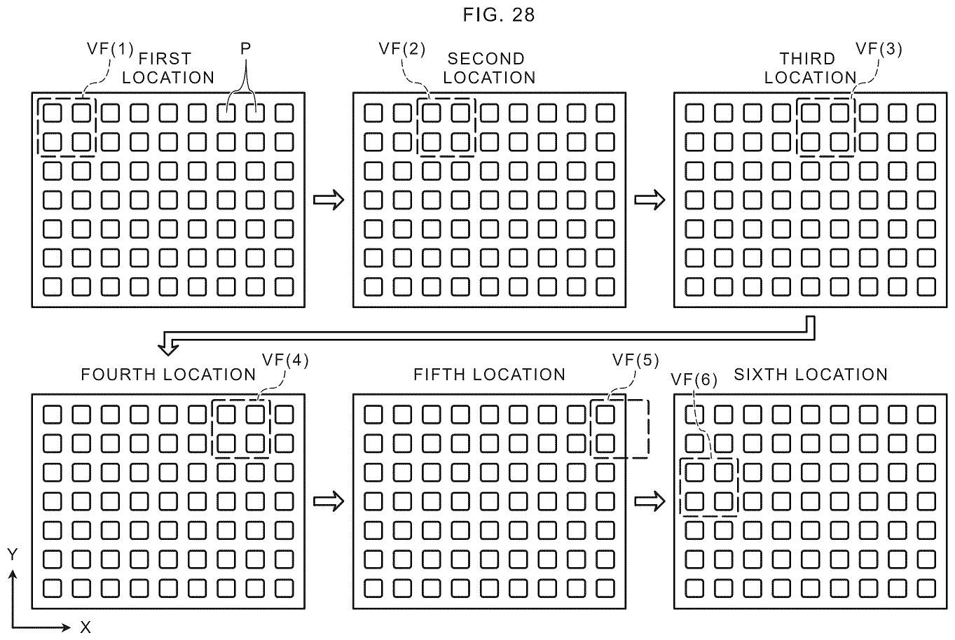

Next, a determination algorithm of (C) the measurement procedure of the electrode pad P among the inspection conditions will be described. FIG. 28 is a diagram for explaining measurement procedures of the electrode pad P.

In the example illustrated in FIG. 28, the electrode pads P are inspected sequentially, starting from the upper side (+Y) of the chip C and from the left side to the right side (+X side). At a first inspection position, the control unit 10 adjusts the relative positions of the 3D shape measuring machine 52 and the wafer W so that the four electrode pads P at an upper left end fit within a measurement field of view VF(1). At a second inspection position, the control unit 10 moves the 3D shape measuring machine 52 to the right side (+X side) with respect to the wafer W so that the electrode pads P that have already been inspected are not included in a measurement field of view VF(2). In this case, the control unit 10 is an example of the measurement field of view moving unit.

When scanning to the +X side is repeated and the inspection of the electrode pad P at the edge of the +X side is completed (fifth location), at a sixth inspection position, the 3D shape measuring machine 52 is moved back to the left side (−X side) with respect to the wafer W and moved to a lower side (−Y side) so that the electrode pads P that have already been inspected are not included in a measurement field of view VF(6). The procedures are repeated sequentially to inspect all of the electrode pads P of the chip C.

In this case, if the number of measurement locations in one chip is denoted by n(p) and the time required to measure one measurement location is denoted by t1(p), the time required to measure one chip denoted by T1(p) is expressed by the following equation, where p denotes the number of pixels of the measurement fields of view VF(1), VF(2), . . .

$$T 1 ( p ) = n ( p ) \times t 1 ( p )$$

Note that while the 3D shape measuring machine 52 is moved back to the −X side after reaching the end part on the +X side in the example illustrated in FIG. 26, the present disclosure is not limited thereto. For example, after the 3D shape measuring machine 52 reaches the end part on the +X side, inspections may be performed in a zigzag pattern while moving the 3D shape measuring machine 52 to the −X side. In addition, for example, inspections may be performed in a spiral pattern such as to the +X-side end part, to the −Y-side end part, to the −X-side end part, and to the +Y-side end part in an uninspected region.

### (Inspection of Electrode Pad P using 3D Shape Measuring Machine 52

After setting the inspection conditions described above, the control unit 10 calculates a feature amount related to the needle mark M from measured data obtained by extracting a surface region of the electrode pad P and determines quality of the electrode pad P. In the present embodiment, the maximum pit depth Sv defined by JIS B 0681-2: 2018 or ISO 25178-2: 2012 is used as the feature amount.

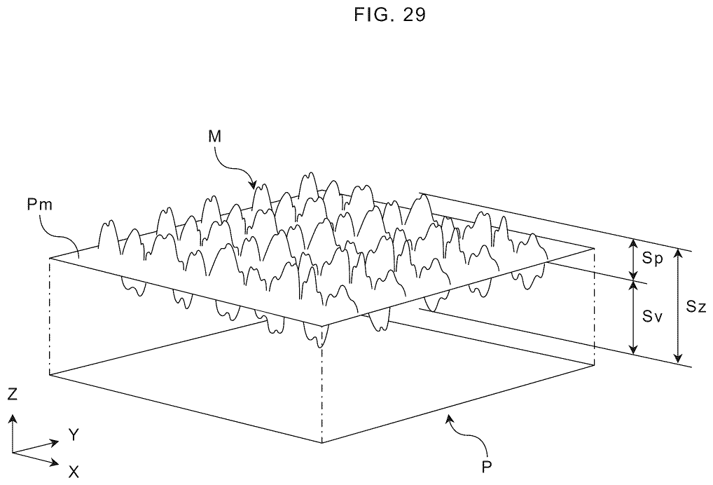

FIG. 29 is a diagram for explaining a feature amount (maximum pit depth Sv) of the needle mark M formed on the electrode pad P. In FIG. 29, a three-dimensional shape (unevenness) of the surface of the electrode pad P is depicted by a curve along the X direction.

The maximum pit depth Sv is an absolute value of a minimum height with respect to an average surface Pm whose height (Z coordinate) is an average value (arithmetic average value) on the surface of electrode pad P. Note that in FIG. 29, Sp denotes a maximum peak height and is a maximum value based on the average surface Pm. In addition, Sz denotes a maximum height indicating a distance from a highest point to a lowest point of the surface of the electrode pad P and satisfies Sz=Sp+Sv.

For example, the control unit 10 makes a determination of quality of the electrode pad P based on a relationship between the maximum pit depth Sv and a design value of thickness of the electrode pad P. Specifically, for example, the electrode pad P is determined as “fail” when the maximum pit depth Sv is equal to or larger than the design value of thickness of the electrode pad P or equal to or larger than 90% of the design value.

Note that the determination is not limited to the example described above. For example, a threshold related to the maximum pit depth Sv of the determination may be changed based on the thickness of the electrode pad P, a ratio of an area of the needle mark M to the electrode pad P, a position, or a strength (brittleness) of the material of the electrode pad P. For example, conceivably, since the thicker the electrode pad P, the less likely the underlying layer is to be exposed, the threshold related to the maximum pit depth Sv may be set to a value closer to the design value of the thickness of the electrode pad P. In addition, conceivably, since the lower the strength of (the brittler) the material of the electrode pad P, the more likely a tear or the like of the electrode pad P is to occur, the threshold related to the maximum pit depth Sv may be set to a value smaller than the design value of the thickness of the electrode pad P.

In addition, conceivably, since a tear or the like of the electrode pad P is more likely to occur when the ratio of the area of the needle mark M to the electrode pad P is equal to or greater than a reference value, when portions other than the needle mark M on the electrode pad P is equal to or less than a reference value, when a distance between the end part of the electrode pad P and the needle mark M is equal to or less than a reference value, and the like, a determination of “fail” may be made. In this case, each reference value may be adjusted according to the strength of the material of the electrode pad P and, for example, the lower the strength of (the brittler) the material of the electrode pad P, the stricter the criteria for making a determination of “fail” may be.

According to the present embodiment, suitably setting inspection conditions by the 3D shape measuring machine 52 enables the electrode pad P to be inspected accurately and at high speed.

While the inspection object is the needle marks M formed on the electrode pad P in the present embodiment, the present disclosure is not limited thereto as described earlier. For example, the present embodiment is also applicable to a visual inspection for detecting an inspection object such as a scratch or a foreign object on the wafer W.

For example, when the inspection object is a scratch on the wafer W, the wafer W may be determined to be abnormal if at least one of the following feature amounts exceeds a reference value: a size of the scratch (for example, a maximum dimension or a minimum dimension), a depth of the scratch (for example, the maximum pit depth Sv or the maximum height Sz), the area of the scratch (for example, a percentage of an area of the scratch per unit area of the wafer W), and an arrangement of the scratch (for example, the number of scratches per unit area or the like). Furthermore, instead of the feature amounts described above or in addition to the feature amounts described above, the wafer W may be determined to be abnormal when a distance between the scratch and the device is equal to or less than a reference value.

In addition, when the inspection object is a foreign object, the wafer W may be determined to be abnormal if at least one of the following feature amounts exceeds a reference value: a size of the foreign object (for example, a maximum dimension or a minimum dimension) and an arrangement of the foreign object (for example, the number of foreign objects per unit area or the like). Furthermore, instead of the feature amounts described above or in addition to the feature amounts described above, the quality of the wafer W may be determined based on a type of the foreign object. For example, if the foreign object is estimated to be easily removable by air or the like based on the three-dimensional shape of the foreign object, the wafer W may be determined to be not abnormal regardless of the feature amounts described above.

In addition, when the inspection object is a scratch or a foreign object, for example, a position of the scratch or the foreign object is detected from an image of the wafer W captured by the 2D camera 50 and inspection object arrangement information related to an arrangement of the inspection object is acquired. Subsequently, a measurement cost may be calculated based on the inspection object arrangement information and a size of the measurement field of view of the 3D shape measuring machine 52.

### Fifth Embodiment

In the present embodiment, while a case where detection of needle marks formed on an electrode pad P of a wafer W is performed after a wafer-level inspection will be described as an example of a visual inspection of a wafer, the present disclosure is not limited thereto. For example, the present embodiment is also applicable to a measurement (detection) of any inspection object (for example, a scratch or a foreign object) on the wafer W.

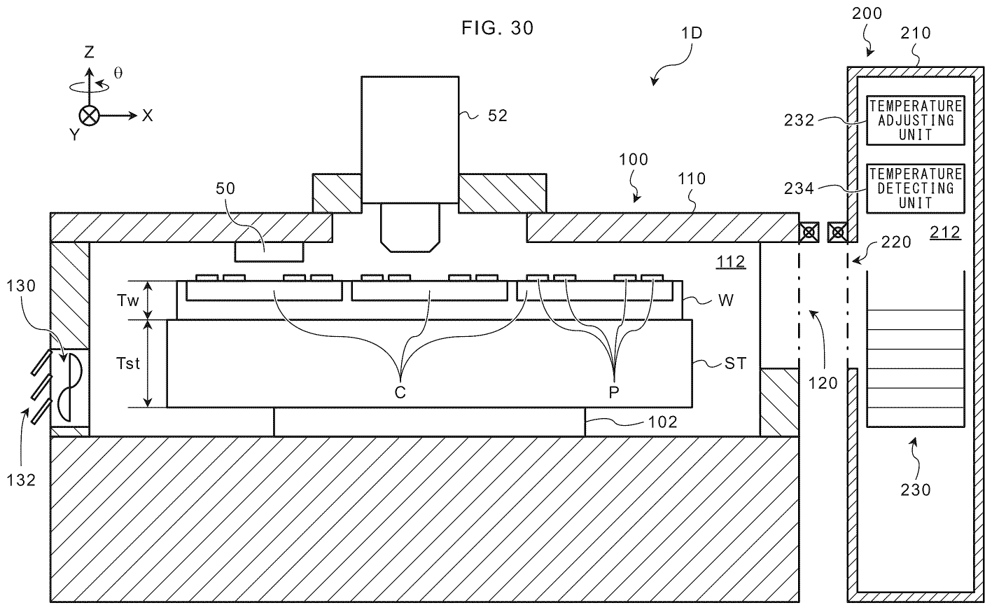

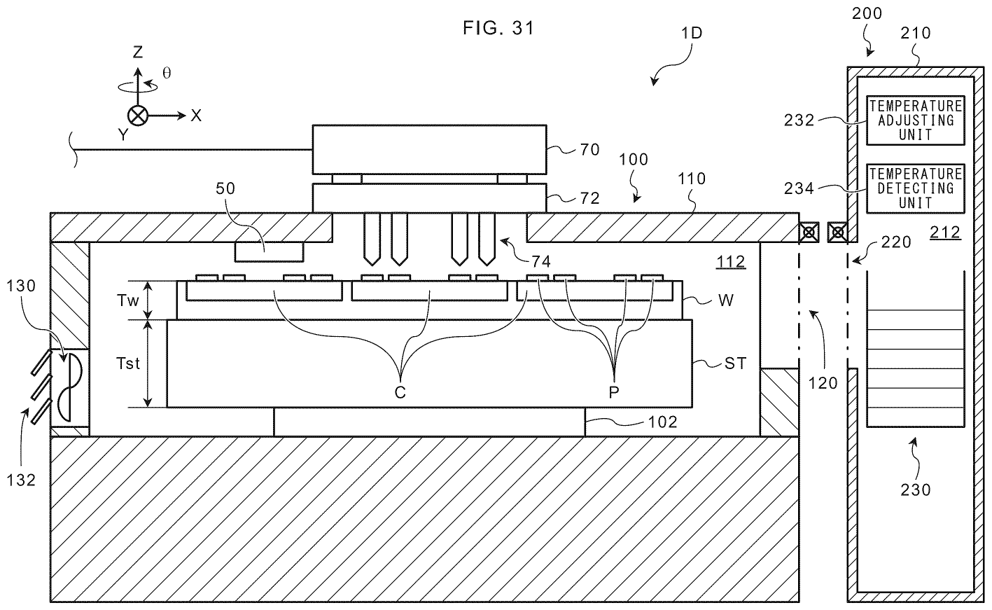

FIGS. 30 and 31 are diagrams illustrating an inspection device according to a fifth embodiment of the present disclosure. FIG. 31 illustrates a state upon execution of a wafer-level inspection, and FIG. 30 illustrates a state upon inspection (detection of needle marks) of the electrode pad P of the wafer W after the wafer-level inspection.

Upon execution of the wafer-level inspection, as illustrated in FIG. 31, the test head 70 is attached to a housing of the measurement unit 100 of an inspection device 1D. Next, the probe needle 74 of the probe card 72 is brought into contact with the electrode pad P formed on a surface of the wafer W that is an inspection object and a test signal is supplied. A signal output by the semiconductor device (chip C) in response to the test signal is then measured by a tester to electrically inspect whether the semiconductor device operates normally. In the wafer-level inspection, a part of an oxide film on a surface of the electrode pad P is scraped off by the probe needle 74, and the probe needle 74 and the electrode pad P become conductive.

Upon inspection of the electrode pad P of the wafer W, as illustrated in FIG. 30, a three-dimensional shape measuring machine (hereinafter, referred to as a “3D shape measuring machine”) 52 is attached to the measurement unit 100 of the inspection device 1D. The 3D shape measuring machine 52 is a device that measures a three-dimensional shape of an inspection object in a contactless manner and that is attached to and detached from a first opening provided on a partition wall 110 of the measurement unit 100.

In the inspection of the electrode pad P of the wafer W, first, an image of the chip C is captured using a 2D camera (for example, an imaging unit for alignment of the wafer W) 50 and electrode pad arrangement information including information related to an arrangement of the electrode pad P in an XY plan view is acquired.

Next, based on the arrangement information of the electrode pad P described above, positioning of the electrode pad P that is an inspection object and the 3D shape measuring machine 52 is performed and an inspection of the electrode pad P is performed by the 3D shape measuring machine 52. The 3D shape measuring machine 52 is a device for measuring a three-dimensional shape of the electrode pad P without coming into contact with the surface of the electrode pad P. A measurement method employed by the 3D shape measuring machine 52 is not particularly limited and examples of measurement methods that can be applied include white light interferometry, SD-OCT (Spectral Domain Optical Coherence Tomography), FD-OCT (Fourier Domain Optical Coherence Tomography), a laser confocal method, a triangulation method, an optical cutting method, a pattern projection method, an optical comb method, and a focus variation method. In addition, as the 3D shape measuring machine 52 using white light interferometry, for example, the 3D shape measuring machine described in Japanese Patent Application Laid-Open No. 2016-080564 or Japanese Patent Application Laid-Open No. 2016-161312 can be applied.

In the inspection of the electrode pad P, a three-dimensional shape of the electrode pad P is measured using the 3D shape measuring machine 52 and a feature amount of the electrode pad P (for example, a maximum pit depth Sv of the needle mark formed in the electrode pad P) is obtained. In this case, the maximum pit depth Sv is a parameter defined by JIS (Japanese Industrial Standards) B 0681-2: 2018 or ISO (International Organization for Standardization) 25178-2: 2012. The maximum pit depth Sv is an absolute value of a minimum height with respect to an average surface Pm whose height (Z coordinate) is an average value (arithmetic average value) on the surface of electrode pad P. When the maximum pit depth Sv exceeds a threshold, since it is likely that the underlying layer is exposed by the needle mark and circuitry is damaged, a determination of “abnormal” (fail) is made. Specifically, based on a relationship between the maximum pit depth Sv and the design value of the thickness of the electrode pad P, the electrode pad P is determined as “fail” when the maximum pit depth Sv is equal to or larger than the design value of the thickness of the electrode pad P or equal to or larger than 90% of the design value.

Note that the determination is not limited to the example described above. For example, a threshold related to the maximum pit depth Sv of the determination may be changed based on the thickness of the electrode pad P, a ratio of an area of the needle mark M to the electrode pad P, a position, or a strength (brittleness) of the material of the electrode pad P. For example, conceivably, since the thicker the electrode pad P, the less likely the underlying layer is to be exposed, the threshold related to the maximum pit depth Sv may be set to a value closer to the design value of the thickness of the electrode pad P. In addition, conceivably, since the lower the strength of (the brittler) the material of the electrode pad P, the more likely a tear or the like of the electrode pad P is to occur, the threshold related to the maximum pit depth Sv may be set to a value smaller than the design value of the thickness of the electrode pad P.

In addition, conceivably, since a tear or the like of the electrode pad P is more likely to occur when the ratio of the area of the needle mark M to the electrode pad P is equal to or greater than a reference value, when portions other than the needle mark M on the electrode pad P is equal to or less than a reference value, when a distance between the end part of the electrode pad P and the needle mark M is equal to or less than a reference value, and the like, a determination of “fail” may be made. In this case, each reference value may be adjusted according to the strength of the material of the electrode pad P and, for example, the lower the strength of (the brittler) the material of the electrode pad P, the stricter the criteria for making a determination of “fail” may be.

While information related to the arrangement of the electrode pad P is acquired using the 2D camera 50 in the present embodiment, the present disclosure is not limited thereto. For example, the acquisition step using the 2D camera 50 may be omitted using design information of the chip C with respect to the arrangement of the electrode pad P. In addition, an image captured by the 2D camera 50 may be compared with the design information of the chip C, and when a difference between the captured image and the design information is equal to or larger than a threshold, information related to the arrangement of the electrode pad P may be acquired from the image captured by the 2D camera 50.

As illustrated in FIGS. 30 and 31, the measurement unit 100 according to the present embodiment has a measuring chamber 112 surrounded by the partition wall (partition) 110 and a wafer-level inspection and an inspection of the electrode pad P are to be performed in the measuring chamber 112.

The partition wall 110 of the measuring chamber 112 is formed of a material with an excellent light-blocking property. For example, a light blocking rate (for example, the light blocking rate based on JIS L 1055: 2009) of the partition wall 110 is preferably 90% or higher. Note that the partition wall 110 may contain a material with high heat insulation properties (low thermal conductivity).

The measuring chamber 112 is separated from outside of the measuring chamber 112 by the partition wall 110. The partition wall 110 functions to separate the air environments inside and outside of the measuring chamber 112. In other words, providing the partition wall 110 suppresses the effects of disturbances (for example, noise, temperature, and vibration) generated outside the measuring chamber 112 on the interior of the measuring chamber 112.

The partition wall 110 has soundproofing performance (vibration control performance). Examples of a structure for realizing the soundproofing performance of the partition wall 110 include filling an internal structure of the partition wall 110 with a sound-absorbing material or fabricating the partition wall 110 so that a resonant frequency of the partition wall 110 itself is higher than a frequency at which noise causes the partition wall 110 to vibrate. In one example, the frequency preferably ranges from 100 to 200 Hz or higher, the frequency may be varied depending on the surrounding environment.

Typically, semiconductor manufacturing plants generate noise from air conditioning and other production equipment, and the level of this noise sometimes exceeds 70 dB. When this noise is transmitted to the stage ST, the noise becomes vibration. If the stage ST vibrates during measurement, the relative distance between the 3D shape measuring machine 52 and the wafer W changes, which may cause measurement errors in the height direction (Z direction) of the inspection object on the wafer W. In this manner, vibrations generated by air conditioning and other production equipment can also cause measurement errors.

In the present embodiment, the partition wall 110 having soundproofing performance can prevent measurement accuracy from declining due to vibration.

Furthermore, in the present embodiment, the partition wall 110 can suppress the effect of radiant heat from outside the measuring chamber 112 on the stage ST and the wafer W and can suppress a decline in measurement accuracy due to deformation (thermal drift) of the wafer W caused by temperature changes. In addition, even if an unevenness of temperature occurs inside the measuring chamber 112 due to a rise in the temperature of the stage ST or the like, the air inside the measuring chamber 112 stabilizes quickly because the air disturbance attributable to the unevenness of temperature is limited to inside the measuring chamber 112.

In addition, the measurement optical system such as the 2D camera 50 and the 3D shape measuring machine 52 may be affected by ambient light from outside the measuring chamber 112. If the 3D shape measuring machine 52 is a confocal type, the 3D shape measuring machine 52 is particularly susceptible to such ambient light. As described above, since the partition wall 110 according to the present embodiment has an excellent light-blocking property, a decline in measurement accuracy attributable to ambient light can be prevented.

Furthermore, as illustrated in FIGS. 30 and 31, the loader unit 200 according to the present embodiment has a preparation chamber 212 surrounded by a partition wall (division) 210 and the wafer W before and after inspections is stored in the preparation chamber 212. The partition wall 210 functions to separate the air environments inside and outside of the preparation chamber 212 in a similar manner to the partition wall 110.

The preparation chamber 212 of the loader unit 200 is blocked from light and shielded from outside air in a similar manner to the measuring chamber 112 of the measurement unit 100 and an environment similar to that of the measuring chamber 112 is reproduced. Rather than directly installing (loading) the wafer W onto the stage ST inside the measuring chamber 112 from outside, having the wafer W temporarily stand-by in the preparation chamber 212 where an environment similar to that of the measuring chamber 112 is being reproduced reduces (preferably, eliminates) a temperature difference between the wafer W and the stage ST or the air inside the measuring chamber 112 at a time point where the wafer W is loaded to the stage ST in the measuring chamber 112. Therefore, measurement errors attributable to unevenness of temperature can be reduced.

Now, to describe measurement errors, for example, when there is a temperature difference between the stage ST and the wafer W, distortion of the wafer W may occur, which may cause measurement accuracy to decline. In addition, when there is a temperature difference between the wafer W and the air inside the measuring chamber 112, a temperature distribution can occur in the air above the wafer W and air disturbances (for example, a refractive index distribution of air) can occur. If a refractive index distribution of air occurs, a fluctuation in optical path lengths can occur in the XY plane during measurement by the 3D shape measuring machine 52. As a result, a flatness in the measurement results by the 3D shape measuring machine 52 may deteriorate, resulting in a degradation of measurement accuracy.

In the present embodiment, providing the loader unit 200 and the preparation chamber 212 enables measurement errors attributable to unevenness of temperature to be reduced and measurement accuracy to be improved. In addition, since a measurement of another wafer W can be performed in the measuring chamber 112 in a standby time slot during which the wafer W is temporarily standing by in the preparation chamber 212, a total time required for measurements can be reduced.

Furthermore, in the present embodiment, a temperature adjusting unit 232 and a temperature detecting unit 234 are provided in the preparation chamber 212 of the loader unit 200 to enable a standby time in the preparation chamber 212 to be reduced. In other words, the temperature of the preparation chamber 212 of the loader unit 200 is kept at a predetermined inspection temperature by the temperature adjusting unit 232 (for example, a heater or a chiller) when performing an inspection of the wafer W. The temperature detecting unit 234 includes a temperature sensor for measuring the temperature inside the preparation chamber 212 and the temperature of the wafer W, and output of the temperature adjusting unit 232 is controlled based on a measurement result by the temperature detecting unit 234. Accordingly, the temperature of the wafer W can be adjusted to the temperature during an inspection in the measuring chamber 112.

Note that a humidity controller and a humidity sensor for adjusting the humidity in the preparation chamber 212 may be provided in the preparation chamber 212. In addition, the temperature adjusting unit 232, the temperature detecting unit 234, the humidity controller, and the humidity sensor may also be omitted.

When the temperature adjusting unit 232 and the temperature detecting unit 234 are provided in the preparation chamber 212 as in the present embodiment, a temperature detecting unit (temperature sensor) may also be provided in the measuring chamber 112.

The stage ST inside the measuring chamber 112 includes a motor, and heat is generated when the motor is operating. Even if a joined part between the preparation chamber 212 and the measuring chamber 112 is made small, air mixing or heat exchange occurs between the preparation chamber 212 and the measuring chamber 112 when shutters 120 and 220 are opened. For this reason, it is difficult to achieve zero heat exchange between the preparation chamber 212 and the measuring chamber 112.

The temperature adjusting unit 232 brings the temperature inside the preparation chamber 212 close to the temperature inside the measuring chamber 112 based on a difference between detected values of temperature by the temperature detecting units provided in the preparation chamber 212 and the measuring chamber 112.

Note that a temperature adjusting unit (for example, a heater or a chiller) may be provided in the measuring chamber 112 in place of the temperature adjusting unit 232 in the preparation chamber 212. In other words, the temperature inside the measuring chamber 112 may be brought close to the temperature inside the preparation chamber 212 based on the difference between detected values of temperature by the temperature detecting units provided in the preparation chamber 212 and the measuring chamber 112. In addition, temperature adjusting units can also be provided in both the measuring chamber 112 and the preparation chamber 212.

The partition wall 210 of the preparation chamber 212 is also formed of a material with an excellent light-blocking property in a similar manner to the partition wall 110 of the measuring chamber 112. In addition, the partition wall 210 may contain a material with high heat insulation properties (low thermal conductivity) in a similar manner to the partition wall 110. Accordingly, the temperature of the wafer W in the preparation chamber 212 is less likely to be transmitted into the measuring chamber 112 and the effect on the measuring chamber 112 is suppressed.

The partition wall 210 also has soundproofing performance (vibration control performance) in a similar manner to the partition wall 110. Examples of a structure for realizing the soundproofing performance of the partition wall 210 include filling an internal structure of the partition wall 210 with a sound-absorbing material or fabricating the partition wall 210 so that a resonant frequency of the partition wall 210 itself is higher than a frequency at which noise causes the partition wall 210 to vibrate. In one example, the frequency preferably ranges from 100 to 200 Hz or higher, while the frequency may be varied depending on the surrounding environment.

In the present embodiment, the partition wall 210 having soundproofing performance can prevent vibration due to sound picked up by the loader unit 200 from being transmitted to the measuring chamber 112 (stage ST) and the 3D shape measuring machine 52. Accordingly, a decline in measurement accuracy attributable to vibration can be prevented.

The partition wall 110 of the measurement unit 100 is provided with a second opening for carrying in and carrying out the wafer W. The second opening is provided with the shutter 120 (an example of the first shutter) which is openable and closable. On the other hand, the partition wall of the loader unit 200 is also provided with an opening for carrying in and carrying out the wafer W. The opening is provided with the shutter 220 (an example of the second shutter) which is openable and closable.

As described above, a conveyance path of the wafer W between the measurement unit 100 and the loader unit 200 is partitioned by the shutters 120 and 220. The shutters 120 and 220 are also formed of a material with an excellent light-blocking property in a similar manner to the partition walls 110 and 210. In addition, the shutters 120 and 220 may contain a material with high heat insulation properties (low thermal conductivity) in a similar manner to the partition walls 110 and 210. Furthermore, when the shutters 120 and 220 are closed, airtightness inside the measuring chamber 112 and the preparation chamber 212 may be maintained. Accordingly, the temperature of the wafer W in the preparation chamber 212 and the like are less likely to be conducted to the measuring chamber 112.

Although FIGS. 30 and 31 illustrate examples of the shutters 120 and 220 that open and close vertically and are retractable, types of shutters are not limited thereto. For example, the type of shutter may be a folding type, a swing-up (spring-up) type, or a sliding type. In addition, a movable partition or the like may be used in place of the shutters 120 and 220 and the partition may be constituted of a hollow member.

The measurement unit 100 and the loader unit 200 may have less physical contact with each other or be kept apart from each other. Accordingly, conduction of heat from the loader unit 200 to the measurement unit 100 can be suppressed, and thermal resistance can be increased.

In addition, a mass of the preparation chamber 212 may be made smaller than a mass of the measuring chamber 112. Furthermore, a joining portion of the measurement unit 100 and the loader unit 200 may be reduced. Accordingly, transmission of vibration generated in the preparation chamber 212 to the 3D shape measuring machine 52 and the measuring chamber 112 of the measurement unit 100 can be suppressed.

The partition wall 110 of the measuring chamber 112 is provided with an opening (example of third opening) for installing a fan 130. The fan 130 circulates air in the measuring chamber 112 to ensure a uniform air environment in the measuring chamber 112. Accordingly, unevenness of temperature in the measuring chamber 112 can be resolved.

A fan shutter 132 is a shutter for opening and closing the opening provided with the fan 130. A type of control of the fan shutter 132 is also not particularly limited and may be an electric type or a manual type that opens and closes electrically or manually or a wind pressure type that opens and closes dynamically by wind pressure. Although FIGS. 30 and 31 illustrate an example including movable louvers as the fan shutter 132, the type of the fan shutter 132 is not limited thereto and may be a retractable type, a foldable type, a swing-up type, or a sliding type.

Note that the fan 130 and the fan shutter 132 can be omitted if air circulation in the measuring chamber 112 can be easily performed, if the volume of the measuring chamber 112 is small, or the like.

According to the present embodiment, providing the partition wall 110 that surrounds the measuring chamber 112 allows the air inside the measuring chamber 112 to be stabilized at an early stage, thereby preventing a decline in the inspection accuracy of a three-dimensional shape attributable to air disturbances.

Note that the loader unit 200 and the preparation chamber 212 can be omitted in the present embodiment. In this case, after placing the wafer W on the stage ST, it is sufficient to wait for a certain period of time until the temperature irregularity is resolved. In this manner, when omitting the loader unit 200 and the preparation chamber 212, a deterioration in measurement accuracy can be prevented by providing a standby time.

### Configuration of Inspection Device

As illustrated in FIGS. 30 and 31, the inspection device 1D according to the present embodiment includes the measurement unit 100 and the loader unit 200 that supplies and retrieves the wafer W that is an inspection object to and from the measurement unit 100. The measurement unit 100 and the loader unit 200 are separable. Note that although the measurement unit 100 and the loader unit 200 can be provided in plurality, only one each is illustrated for the sake of simplicity of description.

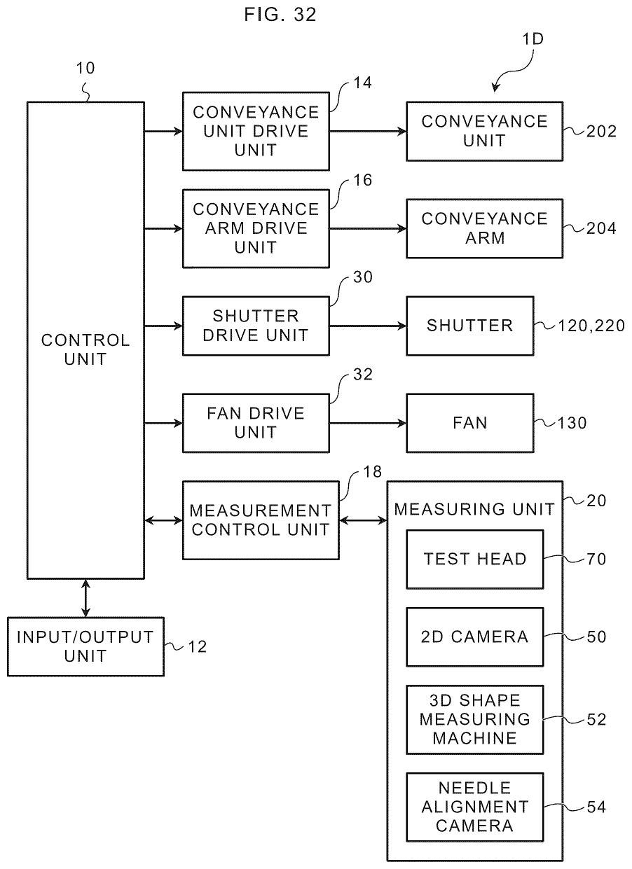

The loader unit 200 has a load port on which a wafer cassette 230 is placed and the conveyance unit 202 (refer to FIG. 32) which conveys the wafer W between each measurement unit 100 and the wafer cassette 230.

When the wafer W is supplied from the loader unit 200 to each measurement unit 100, the wafer W is held by suction on a holding surface of a stage ST of each measurement unit 100.

The stage movement mechanism 102 supports a lower surface (a surface on an opposite side to the holding surface on which the wafer W is held by suction) of the stage ST. The stage movement mechanism 102 is configured to be movable in XYZ directions and rotatable in a θ direction (a rotation direction around the Z direction). Accordingly, due to the stage movement mechanism 102, the wafer W held by suction on the holding surface of the stage ST is movable in the XYZ directions and rotatable in the θ direction together with the stage ST.

In the present embodiment, an adjustment may be made so that a heat capacity of the stage ST increases. For example, the heat capacity of the stage ST may be increased by making a thickness Tst of the stage ST thicker than a thickness Tw of the wafer W that is a measurement object (in one example, Tst≥3×Tw). Accordingly, an effect of the heat of the wafer W on the environment (for example, temperature) in the measuring chamber 112 can be suppressed.

As illustrated in FIG. 31, upon execution of the wafer-level inspection, the test head 70 is attached to the measurement unit 100 of the inspection device 1D.

The probe card 72 is provided at a position opposing the stage ST and arranged approximately parallel to the holding surface of the stage ST. Probe needles 74 are formed on the surface opposing the stage ST of the probe card 72. The probe card 72 is connected to a tester body via the test head 70.

Chips C are formed on the wafer W and each chip C includes one or more electrode pads P. By moving the stage ST in the XYZ directions or rotating the stage ST in the θ direction with the stage movement mechanism 102, positioning of the wafer W and the probe card 72 is performed so as to bring each probe needle 74 into contact with a corresponding electrode pad P.

After positioning and contact of the probe needle 74 and the electrode pad P by the inspection device 1D, an electric signal is sent to the chip C from the tester body via the test head 70, the probe card 72, and the probe needle 74 to perform an inspection (wafer-level inspection) of electrical characteristics of the chip C on the wafer W. A result of the inspection of electrical characteristics is output by the input/output unit 12 (refer to FIG. 32) in a form that can be checked by an operator.

After the end of the inspection of electrical characteristics of the chip C on the wafer W, the wafer W is conveyed from the inspection device 1D to the loader unit 200 by a conveyance unit to be retrieved.

As illustrated in FIG. 30, the 3D shape measuring machine 52 is attached to the measurement unit 100 of the inspection device 1D during the inspection of the electrode pad P of the wafer W. In addition, needle marks formed in the electrode pad P by the wafer-level inspection are sequentially detected by the 3D shape measuring machine 52 to perform quality determination of the needle marks formed on the electrode pad P.

While the 2D camera 50 and the 3D shape measuring machine 52 are separately attached in the present embodiment, the present disclosure is not limited thereto. For example, the 2D camera 50 and the 3D shape measuring machine 52 may be made interchangeable by a revolver mechanism.

In addition, the test head 70, the 2D camera 50, the 3D shape measuring machine 52, and the like and the stage ST need only be relatively movable and the test head 70, the 2D camera 50, the 3D shape measuring machine 52, and the like may be made movable with respect to the stage ST.

### Control System of Inspection Device

FIG. 32 is a block diagram illustrating a control system of the inspection device according to the fifth embodiment of the present disclosure.

As illustrated in FIG. 32, the inspection device 1D according to the present embodiment includes the control unit 10, the input/output unit 12, the conveyance unit drive unit 14, the conveyance arm drive unit 16, and the measurement control unit 18.

The control unit 10 includes a processor (for example, a CPU (Central Processing Unit) or an MPU (Micro Processor Unit)), a ROM (Read Only Memory), a RAM (Random Access Memory), and a storage device (for example, an HDD (Hard Disk Drive) or an SSD (Solid State Drive)). In the control unit 10, functions of various units of the inspection device 1D are realized by the processor by executing various programs such as a control program stored in the storage device.

The input/output unit 12 includes a display unit (for example, a liquid crystal display) that displays a GUI (Graphical User Interface) or the like for operating the inspection device 1D and an operating unit (for example, a touch panel, a keyboard, or a pointing device) for receiving operation input from an operator.

The conveyance unit drive unit 14 includes a motor or the like for moving the conveyance unit 202 in the XYZ directions and rotating the conveyance unit 202 in the θ direction (around the Z direction) inside the loader unit 200.

The conveyance arm drive unit 16 includes a motor for extending and contracting the conveyance arm 204 attached to the conveyance unit 202 in a length direction of the conveyance arm 204 and a control valve for suctioning the wafer W to a suction hole of the conveyance arm 204. The control valve is connected to a vacuum (pump) provided at an installation side of the inspection device 1D.

A shutter drive unit 30 includes a motor or the like for opening and closing the shutter 120 on a side of the measurement unit 100 and the shutter 220 on a side of the loader unit 200. When conveying the wafer W between the measurement unit 100 and the loader unit 200, the shutters 120 and 220 are opened, and when not conveying, the shutters 120 and 220 are closed.

A fan drive unit 32 includes a motor or the like for driving the fan 130 of the measuring chamber 112. In addition, when the fan shutter 132 is an electrically operated type, the fan drive unit 32 includes a motor or the like for opening and closing the fan shutter 132. The fan 130 is stopped during an inspection of the electrode pad P by the 3D shape measuring machine 52 but otherwise, such as when unevenness of temperature is detected by the temperature sensor inside the measuring chamber 112 or the like, the air inside the measuring chamber 112 can be circulated by the fan 130 if necessary.

The control unit 10 controls the opening and closing of the shutters 120 and 220 by the shutter drive unit 30. In addition, the control unit 10 controls the conveyance unit 202 and the conveyance arm 204 by the conveyance unit drive unit 14 and the conveyance arm drive unit 16, respectively, to retrieve the wafer W from wafer cassettes and to carry the wafer W into and out from the measurement units 100.

Furthermore, the control unit 10 may acquire a measurement result of the temperature in the preparation chamber 212 by the temperature detecting unit 234 and control the temperature adjusting unit 232 based on the measurement result.

The needle alignment camera 54 is a device for detecting a tip position of the probe needle 74 and is provided on, for example, the stage ST. The control unit 10 performs positioning of the probe needle 74 and the electrode pad P based on a detection result of the tip position of the probe needle 74 and a detection result of the electrode pad P by the 2D camera 50.

The measurement control unit 18 performs, according to a control signal from the control unit 10, drive control of the test head 70 for inspection of the wafer W provided in the measurement unit 100, imaging control of the 2D camera 50, measurement control of the 3D shape measuring machine 52, and imaging control of the needle alignment camera 54. As the test head 70 and the 2D camera 50, for example, the test head and the 2D camera described in Japanese Patent Application Laid-Open No. 2019-102591 can be used.

According to the present embodiment, surrounding the measuring chamber 112 with the partition wall 110 having a light-blocking property enables an effect of a disturbance to the inside of the measuring chamber 112 to be minimized and prevents a decline in inspection accuracy of a three-dimensional shape attributable to air disturbance.

### First Modification of Fifth Embodiment

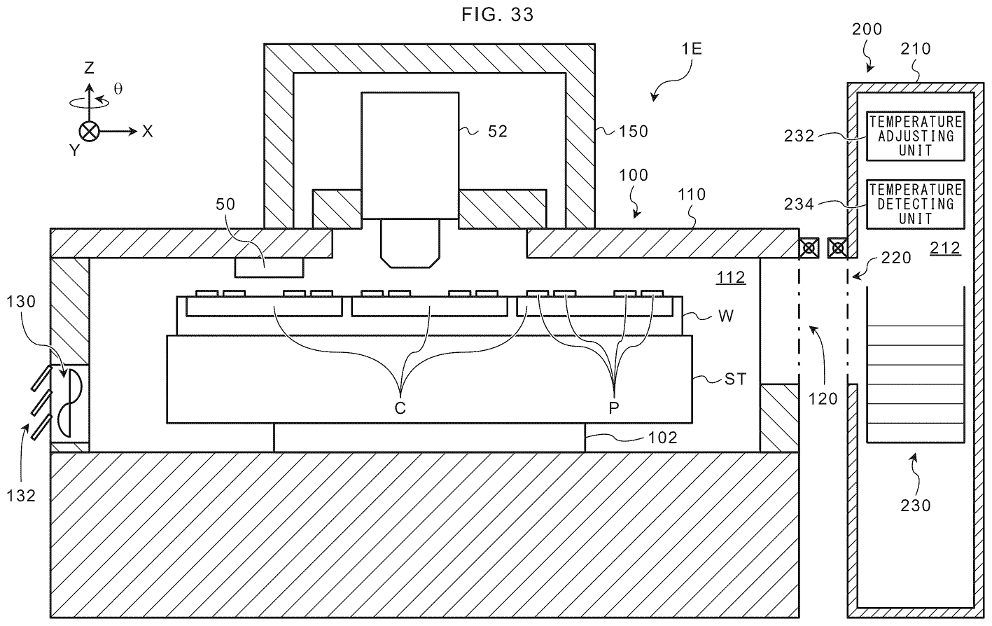

FIG. 33 is a diagram (during wafer-level inspection) illustrating an inspection device according to a first modification of the fifth embodiment. In the following description, configurations that are common or similar to the above embodiments will be designated by same or subscripted reference numerals or characters, and descriptions thereof will not be repeated.

As illustrated in FIG. 33, in an inspection device 1E according to the first modification, when the 3D shape measuring machine 52 is attached to the measurement unit 100, the 3D shape measuring machine 52 is covered with a cover 150 having a rectangular parallelopiped shape or a cylindrical shape. The cover 150 is also formed of a material with an excellent light-blocking property in a similar manner to the partition walls 110 and 210. In addition, the cover 150 may contain a material with high heat insulation properties (low thermal conductivity) in a similar manner to the partition walls 110 and 210.

As illustrated in FIG. 33, the 3D shape measuring machine 52 is mounted in a space separated from the outside of the cover 150. The cover 150 functions to separate the air environments inside and outside of the cover 150. In other words, providing the cover 150 suppresses the effects of disturbances (for example, noise, temperature, and vibration) generated outside the cover 150.

The cover 150 has soundproofing performance (vibration control performance) in a similar manner to the partition walls 110 and 210. Examples of a structure for realizing the soundproofing performance of the cover 150 include filling an internal structure of the cover 150 with a sound-absorbing material or fabricating the cover 150 so that a resonant frequency of the cover 150 itself is higher than a frequency at which noise causes the cover 150 to vibrate. In one example, the frequency preferably ranges from 100 to 200 Hz or higher, while the frequency may be varied depending on the surrounding environment.

Typically, semiconductor manufacturing plants generate noise from air conditioning and other production equipment, and the level of this noise sometimes exceeds 70 dB. When this noise is transmitted to the 3D shape measuring machine 52, the noise becomes vibration. If the 3D shape measuring machine 52 vibrates during measurement, the relative distance between the 3D shape measuring machine 52 and the wafer W changes, which may cause measurement errors in the height direction (Z direction) of the inspection object on the wafer W. In this manner, vibrations generated by air conditioning and other production equipment can also cause measurement errors.

In types of the 3D shape measuring machine 52 that use a white interference microscope, focus variations, or the like, vibration can also be transmitted between a scale on a scanning axis and a scale head. Since this type of device generally performs imaging in response to a trigger signal output according to a reading position of the scale, the transmission of vibrations may cause a maximum frame rate of an imaging unit included in the device to be exceeded and may cause a frame drop. Such a frame drop can also cause measurement errors.

In the present embodiment, the cover 150 having soundproofing performance can prevent measurement accuracy from declining due to the vibration described above.

Furthermore, in the present embodiment, the cover 150 can suppress the effects of external radiant heat on the 3D shape measuring machine 52, supporting members thereof, and the like. In addition, a decline in measurement accuracy due to deformation (thermal drift) of support members and the like attributable to temperature changes or due to thermal effects on the measurement optical system of the 3D shape measuring machine 52 can be suppressed.

### Second Modification of Fifth Embodiment

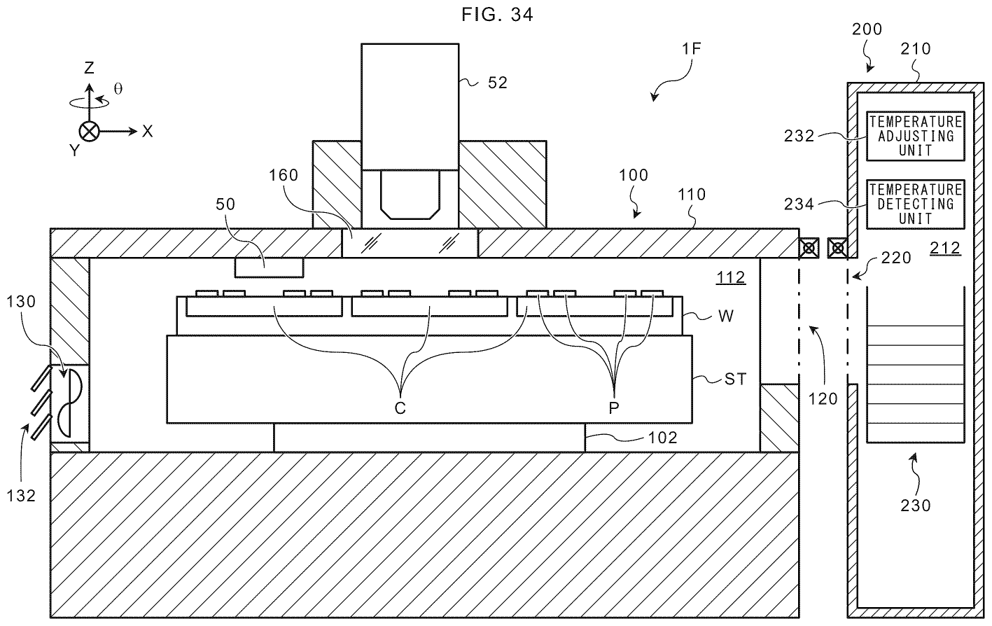

FIG. 34 is a diagram (during wafer-level inspection) illustrating an inspection device according to a second modification of the fifth embodiment.

As illustrated in FIG. 34, in an inspection device 1F according to the second modification, a transparent member 160 is attached (for example, fitted) to an opening in an upper part of the measurement unit 100 during a wafer-level inspection and the 3D shape measuring machine 52 performs an inspection of the electrode pad P of the wafer W from outside the measuring chamber 112. In this case, the transparent member 160 may contain a material with high heat insulation properties (low thermal conductivity). Note that when the test head 70 is attached, the transparent member 160 is removed and the opening in the upper part of the measurement unit 100 is opened.

Due to the transparent member 160, the effects of external radiant heat on the 3D shape measuring machine 52, supporting members thereof, and the like can be suppressed. In addition, a decline in measurement accuracy due to deformation (thermal drift) of support members and the like attributable to temperature changes or due to thermal effects on the measurement optical system of the 3D shape measuring machine 52 can be suppressed.

### Third Modification of Fifth Embodiment

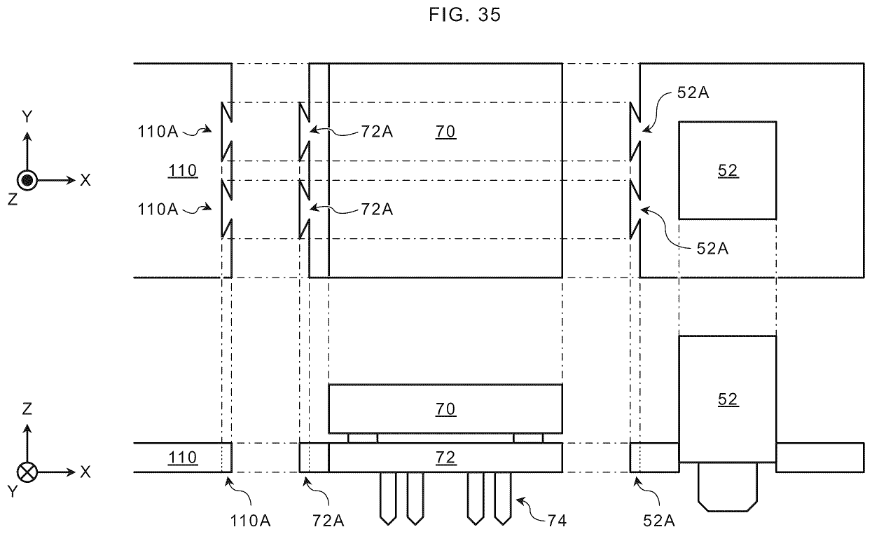

FIG. 35 is a diagram illustrating the test head 70 and the 3D shape measuring machine 52 in an inspection device according to a third modification of the fifth embodiment. An upper view in FIG. 35 is a plan view from the +Z side and a lower view in FIG. 35 is a side view from the −Y side.

As illustrated in FIG. 35, the third modification represents a common shape of an attaching unit when attaching the test head 70 and the 3D shape measuring machine 52 to the measurement unit 100.

As illustrated in FIG. 35, an attaching unit 110A for attaching the test head 70 and the 3D shape measuring machine 52 is formed on the partition wall 110 on an upper surface of the measurement unit 100.

An attaching unit 72A of the test head 70 and an attaching unit 52A of the 3D shape measuring machine 52 have shapes that are approximately congruent in a plan view (viewed from the Z direction) and can be attached (fitted) to the attaching unit 110A. The attaching units 110A, 72A, and 52A are examples of the first to third attaching units, respectively.

While the attaching unit 110A has a female dovetail form and the attaching unit 72A of the test head 70 and the attaching unit 52A of the 3D shape measuring machine 52 have a male dovetail form in the example illustrated in FIG. 35, the shapes of the attaching units are not limited thereto. For example, in addition to the fitting structure described above, auxiliary fixtures such as screws or joints may be used to provide auxiliary fixation between the partition wall 110 and the test head 70 or between the partition wall 110 and the 3D shape measuring machine 52. The shape of the attaching units 72A and 52A may be any shape that allows the attaching units 72A and 52A to be attached to the attaching unit 110A. For example, the shape can be a concavo-convex shape, a rabbet (shiplap) shape where the attaching units 72A and 52A and the attaching unit 110A are partially chipped off from each other, a dovetail rabbet shape, or the like.

The third modification facilitates the attachment and replacement of the test head 70 and the 3D shape measuring machine 52 with respect to the measurement unit 100.

In addition, a relationship between attaching positions of the test head 70 and the 3D shape measuring machine 52 is determined by the attaching units. Therefore, for example, information related to the position of the measurement field of view of the 3D shape measuring machine 52 can be obtained after a wafer-level inspection. In other words, information related to a location probed in a preceding wafer-level inspection (probing information) can be readily obtained, and information related to electrical characteristics (for example, which electrode pad P had abnormal electrical characteristics) can also be used.

According to the third modification, since the partition wall 110 on the upper surface of the measurement unit 100 and the test head 70 and the 3D shape measuring machine 52 are given fitting structures, reproducibility of attachment can be maintained. Therefore, when attaching the 3D shape measuring machine 52, a mutual positional relationship between the 3D shape measuring machine 52 and the 2D camera 50 after the attachment can be easily calibrated. In addition, while the required positional accuracy between the 3D shape measuring machine 52 and the 2D camera 50 differs for each measurement object, depending on the required positional accuracy, calibration of the positional relationship between the two may not be necessary. On the other hand, even when attaching the test head 70, calibration of the mutual positional relationship between the test head 70 and the 2D camera 50 after attachment is facilitated (for example, the test head 70 fits within the field of view of the 2D camera 50), and depending on the required positional accuracy, calibration of the positional relationship between the two may not be necessary.

### Inspection Method According to Fifth Embodiment

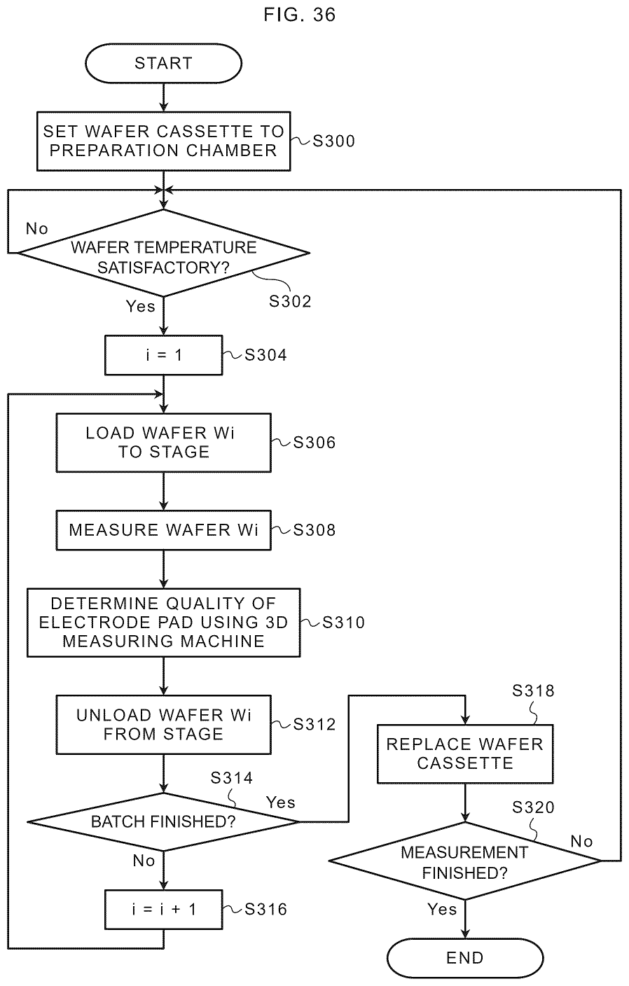

FIG. 36 is a flowchart illustrating an inspection method according to the fifth embodiment of the present disclosure.

First, before an inspection, both the shutter 120 on the side of the measurement unit 100 and the shutter 220 on the side of the loader unit 200 are closed.

The wafer cassette 230 (for example, a batch of N-number of wafers W) is set to the preparation chamber 212 of the loader unit 200 (step S300) and an inspection of the batch of wafers W is started. A start instruction of the inspection may be accepted as a manual instruction via a measurement start button of the input/output unit 12 or the like or the inspection may be automatically started at a time point where the wafer cassette 230 is set and the partition wall 210 of the loader unit 200 is closed.

Next, the temperature adjusting unit 232 and the temperature detecting unit 234 perform temperature control inside the preparation chamber 212. The temperature adjusting unit 232 and the temperature detecting unit 234 stand by until the temperature of the wafers W in the preparation chamber 212 reach a predetermined inspection temperature (temperature equivalent to the temperature of the measuring chamber 112: for example, the temperature of the measuring chamber 112±2° C.) (step S302).

While the temperature adjusting unit 232 and the temperature detecting unit 234 stand by after actually detecting the temperature in the preparation chamber 212 in step S302, the present disclosure is not limited thereto. For example, the control unit 10 may be programmed to operate so that after a predetermined amount of time has elapsed after the inspection has started, the control unit 10 automatically transitions to step S304. The predetermined amount of time in this case can be determined experimentally or empirically according to, for example, data on temperature changes after the partition wall 210 of the loader unit 200 is closed or after the temperature adjusting unit 232 begins operating.

Next, a parameter i for the number of wafers W that are inspection objects is set to i =1 (step S304), and a wafer-level inspection and an inspection of the electrode pad P (quality determination) with respect to a wafer W1 are performed in sequence. When performing the wafer-level inspection, the test head 70 is attached to the measurement unit 100. In addition, the shutter 120 on the side of the measurement unit 100 and the shutter 220 on the side of the loader unit 200 are opened and the first wafer W1 is loaded to the stage ST (step S306). The shutters 120 and 220 are closed after the wafer W1 is loaded, the measuring chamber 112 is separated from outside and the loader unit 200, and the effect of disturbance from the outside and the loader unit 200 on the measuring chamber 112 is suppressed.

Next, the test head 70 executes a wafer-level inspection of the wafer W1 (step S308). A result of the wafer-level inspection is output to the control unit 10.

After the wafer-level inspection, a quality determination of the electrode pad P is performed using the 3D shape measuring machine 52 (step S310). While a shape measurement of the electrode pad P using the 3D shape measuring machine 52 is being performed in step S310, the operation of the fan 130 is stopped and the fan shutter 132 is closed. In addition, the shutters 120 and 220 remain closed.

Once the wafer-level inspection of the wafer W1 (step S308) and the inspection of the electrode pad P (step S310) end, the shutter 120 on the side of the measurement unit 100 and the shutter 220 on the side of the loader unit 200 are opened and the wafer W1 is unloaded from the stage ST (step S312). The shutters 120 and 220 are closed after the wafer W1 is unloaded.

Next, the parameter i for the number of wafers W is set to i=i+1 (No in step S314, step S316), and a wafer-level inspection (step S308) of a next wafer W2 and an inspection (step S310) of the electrode pad P are performed. Note that unloading of the wafer W1 and loading of the wafer W2 can be performed in parallel. In this case, the shutters 120 and 220 may be closed after both unloading of the wafer W1 and loading of the wafer W2 are completed.

Once the wafer-level inspection of the wafers Wi in the batch that is the inspection object (step S308) and the inspection of the electrode pad P (step S310) end by repeating steps S306 to S316 (Yes in step S314), the wafer cassette 230 in the loader unit 200 is replaced (step S318), and an inspection of a next batch (steps S302 to S316) is performed. Once the inspections of all of the batches that are inspection objects end (Yes in step S320), the inspection flow is ended.

According to the present embodiment, the measuring chamber 112 is surrounded by the partition wall 110 having a light-blocking property and the opening of the shutters 120 and 220 is limited to when the wafers Wi are loaded and unloaded. Accordingly, an effect of a disturbance to the inside of the measuring chamber 112 can be minimized and a decline in inspection accuracy of a three-dimensional shape attributable to air disturbance can be suppressed.

While the inspection object is the needle marks M formed on the electrode pad P in the present embodiment, the present disclosure is not limited thereto as described earlier. For example, the present embodiment is also applicable to a visual inspection for detecting an inspection object such as a scratch or a foreign object on the wafer W.

For example, when the inspection object is a scratch on the wafer W, the wafer W may be determined to be abnormal if at least one of the following feature amounts exceeds a reference value: a size of the scratch (for example, a maximum dimension or a minimum dimension), a depth of the scratch (for example, the maximum pit depth Sv or the maximum height Sz), the area of the scratch (for example, a percentage of an area of the scratch per unit area of the wafer W), and an arrangement of the scratch (for example, the number of scratches per unit area or the like). Furthermore, instead of the feature amounts described above or in addition to the feature amounts described above, the wafer W may be determined to be abnormal when a distance between the scratch and the device is equal to or less than a reference value.

In addition, when the inspection object is a foreign object, the wafer W may be determined to be abnormal if at least one of the following feature amounts exceeds a reference value: a size of the foreign object (for example, a maximum dimension or a minimum dimension) and an arrangement of the foreign object (for example, the number of foreign objects per unit area or the like). Furthermore, instead of the feature amounts described above or in addition to the feature amounts described above, the quality of the wafer W may be determined based on a type of the foreign object. For example, if the foreign object is estimated to be easily removable by air or the like based on the three-dimensional shape of the foreign object, the wafer W may be determined to be not abnormal regardless of the feature amounts described above.

### Reference Signs List

1, 1A to 1F: inspection device, 10: control unit, 12: input/output unit, 14: conveyance unit drive unit, 16: conveyance arm drive unit, 18: measurement control unit, 20: measuring unit, 50: 2D camera, 52: 3D shape measuring machine, 54: needle alignment camera, 70: test head, 100: measurement unit, 110: partition wall, 112: measuring chamber, 120: shutter, 150: cover, 160: transparent member, 200: loader unit, 210: partition wall, 212: preparation chamber, 220: shutter.

What is claimed is:

1. An inspection device, comprising:
a camera configured to capture an image of an inspection object on a wafer;
a first determining unit configured to detect the inspection object from the image captured by the camera and make a tentative determination of quality of the inspection object;
a three-dimensional shape measuring machine configured to measure a three-dimensional shape of the inspection object determined to be abnormal by the tentative determination; and
a second determining unit configured to make a formal determination of the quality of the inspection object based on the three-dimensional shape of the inspection object measured by the three-dimensional shape measuring machine and the image captured by the camera or based on the three-dimensional shape of the inspection object measured by the three-dimensional shape measuring machine.

2. The inspection device according to claim 1,
wherein the inspection object includes a needle mark formed on an electrode pad of the wafer when electrically inspecting the wafer using a test head.

3. The inspection device according to claim 2,
wherein the first determining unit detects an area of a needle mark formed on the electrode pad from the image captured by the camera and makes a tentative determination of quality of the electrode pad based on the area.

4. The inspection device according to claim 2,
wherein the second determining unit makes a formal determination of quality of the electrode pad based on a maximum pit depth of the electrode pad measured by the three-dimensional shape measuring machine.

5. The inspection device according to claim 1, further comprising
an alignment unit configured to acquire a positional relationship between the camera and the three-dimensional shape measuring machine.

6. The inspection device according to claim 5,
wherein the alignment unit acquires a positional relationship between the camera and the three-dimensional shape measuring machine based on measurement results of an alignment mark by the camera and the three-dimensional shape measuring machine.

7. An inspection method, comprising:
capturing an image of an inspection object on a wafer with a camera, detecting the inspection object from the image, and making a tentative determination of quality of the inspection object; and
measuring a three-dimensional shape of the inspection object determined to be abnormal by the tentative determination with a three-dimensional shape measuring machine and making a formal determination of the quality of the inspection object based on the three-dimensional shape of the inspection object measured by the three-dimensional shape measuring machine and the image captured by the camera or based on the three-dimensional shape of the inspection object measured by the three-dimensional shape measuring machine.

8. The inspection method according to claim 7,
wherein the inspection object includes a needle mark formed on an electrode pad of the wafer when electrically inspecting the wafer using a test head.

9. The inspection method according to claim 7, further comprising
an alignment step of acquiring a positional relationship between the camera and the three-dimensional shape measuring machine.

10. The inspection method according to claim 9, further comprising:
measuring an alignment mark with the camera; and
measuring the alignment mark with the three-dimensional shape measuring machine, wherein
in the alignment step, a positional relationship between the camera and the three-dimensional shape measuring machine is acquired based on measurement results of the alignment mark by the camera and the three-dimensional shape measuring machine.
